(19) United States
(12) Patent Application Publication
(10) Pub. No.: US 2025/0226315 A1
(43) Pub. Date: Jul. 10, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Kohji KANAMORI, Suwon-si (KR); Seogoo KANG, Suwon-si (KR); Kyungdong KIM, Suwon-si (KR); Junghoon JUN, Suwon-si (KR); Jeehoon HAN, Suwon-si (KR)

(73) Assignee: Samsung Electronics Co., Ltd., Suwon-si (KR)

(21) Appl. No.: 18/799,205

(22) Filed: Aug. 9, 2024

(30) Foreign Application Priority Data
Jan. 4, 2024 (KR) 10-2024-0001555

(51) Int. Cl. H01L 23/528; G11C 5/06; G11C 16/04; H01L 25/065; H10B 41/10; H10B 41/27; H10B 41/35; H10B 41/41; H10B 43/10; H10B 43/27; H10B 43/35; H10B 43/40; H10B 80/00

(52) U.S. Cl. CPC H01L 23/5283; G11C 5/063; G11C 16/0483; H01L 25/0655; H10B 41/10; H10B 41/27; H10B 41/35; H10B 41/41; H10B 43/10; H10B 43/27; H10B 43/35; H10B 43/40; H10B 80/00

(57) ABSTRACT

A semiconductor device includes a peripheral circuit structure including a circuit substrate, a lower cell array structure overlapping the peripheral circuit structure and including lower vertical channel structures and lower bit lines, and an upper cell array structure including upper vertical channel structures and upper bit lines, wherein the lower bit lines include a first lower bit line connected to a first group of the lower vertical channel structures and a second lower bit line connected to a second group of the lower vertical channel structures, the first and second lower bit lines are at a first level, and the upper bit lines include an upper bit line at a second level farther from the circuit substrate than the first level and connected to some of the upper vertical channel structures, and an upper connection bit line connected to the upper bit line.

### CROSS-REFERENCE TO RELATED APPLICATION

This application is based on and claims priority under 35 U.S.C. § 119 to Korean Patent Application No. 10-2024-0001555, filed on Jan. 4, 2024, in the Korean Intellectual Property Office, the disclosure of which is incorporated by reference herein in its entirety.

### BACKGROUND

The inventive concepts relate to a semiconductor device and an electronic system including the semiconductor device, and more particularly, to a semiconductor device including a nonvolatile vertical memory device and an electronic system including the semiconductor device.

Semiconductor devices configured to store large amounts of data are required in electronic systems requiring data storage. Therefore, to increase the data storage capacity of semiconductor devices, semiconductor devices including vertical memory devices including 3-dimensionally arranged memory cells have been proposed.

### SUMMARY

The inventive concepts provide a semiconductor device including 3-dimensionally arranged memory cells and having improved reliability by minimizing and/or reducing the difference in operation speeds between a plurality of cell array structures overlapping each other in the vertical direction to improve the degree of integration.

The inventive concepts also provides an electronic system that includes a semiconductor device including 3-dimensionally arranged memory cells and having increased performance by minimizing and/or reducing the difference in operation speed between a plurality of cell array structures overlapping each other in the vertical direction to improve the degree of integration.

According to an aspect of the inventive concepts, there is provided a semiconductor device including a peripheral circuit structure comprising a circuit substrate and a plurality of circuits on the circuit substrate; a lower cell array structure overlapping the peripheral circuit structure in a vertical direction, the lower cell array structure comprising a plurality of lower vertical channel structures; an upper cell array structure overlapping the peripheral circuit structure in the vertical direction such that the lower cell array structure is between the peripheral circuit structure and the upper cell array structure, the upper cell array structure comprising a plurality of upper vertical channel structures; and a plurality of bit lines including a plurality of lower bit lines connected the plurality of lower vertical channel structures and a plurality of upper bit lines connected to the plurality of upper vertical channel structures, wherein the plurality of lower bit lines comprise a first lower bit line connected to a first group of the plurality of lower vertical channel structures, and a second lower bit line connected to a second group of the plurality of lower vertical channel structures, the second group selected from a remainder of the plurality of lower vertical channel structures which are spaced apart from the first group of lower vertical channel structures, wherein the first lower bit line and the second lower bit line are spaced apart from each other in a first horizontal direction and extend along a first straight line in the first horizontal direction at a first vertical level over the circuit substrate, and the plurality of upper bit lines comprise an upper bit line connected to a first group of the plurality of upper vertical channel structures, and an upper connection bit line connected to the upper bit line, wherein the upper bit line connected to the first group of upper vertical channel structures is at a second vertical level and the upper connection bit line is at the first vertical level, and wherein the second vertical level is farther from the circuit substrate than the first vertical level.

According to another aspect of the inventive concepts, there is provided a semiconductor device including a peripheral circuit structure comprising a circuit substrate and a plurality of circuits on the circuit substrate; a lower cell array structure overlapping the peripheral circuit structure in a vertical direction, the lower cell array structure comprising a plurality of lower vertical channel structures; an insulating structure passing through a portion of the lower cell array structure in the vertical direction; an upper cell array structure overlapping the peripheral circuit structure in the vertical direction such that the lower cell array structure is between the peripheral circuit structure and the upper cell array structure, the upper cell array structure comprising a plurality of upper vertical channel structures; a plurality of bit lines including a plurality of lower bit lines connected the plurality of lower vertical channel structures and a plurality of upper bit lines connected to the plurality of upper vertical channel structures; and a plurality of through-contact plugs passing through the insulating structure in the vertical direction, wherein the plurality of lower bit lines comprise a first lower bit line connected to a first group of the plurality of lower vertical channel structures, and a second lower bit line connected to a second group of the plurality of lower vertical channel structures, the second group selected from a remainder the plurality of lower vertical channel structures which are apart from the first group of lower vertical channel structures, wherein the first lower bit line and the second lower bit line are spaced apart from each other in a first horizontal direction, with the insulating structure and the plurality of through-contact plugs therebetween, and the plurality of upper bit lines comprise an upper bit line connected to a first group of the plurality upper vertical channel structures, and an upper connection bit line connected the upper bit line through at least one of the plurality of through-contact plugs, wherein first lower bit line, the upper connection bit line, and the second lower bit line are sequentially arranged on a first straight line at a first vertical level.

According to another aspect of the inventive concepts, there is provided an electronic system including a main substrate; a semiconductor device on the main substrate; and a controller on the main substrate and electrically connected to the semiconductor device, wherein the semiconductor device comprises a peripheral circuit structure comprising a circuit substrate and a plurality of circuits on the circuit substrate, a lower cell array structure overlapping the peripheral circuit structure in a vertical direction, the lower cell array structure comprising a plurality of lower vertical channel structures, an upper cell array structure overlapping the peripheral circuit structure in the vertical direction such that the lower cell array structure is between the upper cell array structure and the peripheral circuit structure, the upper cell array structure comprising a plurality of upper vertical channel structures, a plurality of bit lines, the plurality of bit lines including a plurality of lower bit lines connected the plurality of lower vertical channel structure, and a plurality of upper bit lines connected to the plurality of upper vertical channel structures, and an input/output pad electrically connected to the peripheral circuit structure, wherein the plurality of lower bit lines comprise a first lower bit line connected to a first group of the plurality of lower vertical channel structures, and a second lower bit line connected to a second group of the plurality of lower vertical channel structures, the second group selected from a remainder of the plurality of lower vertical channel structures which are apart from the first group of lower vertical channel structures, wherein the first lower bit line and the second lower bit line are spaced apart from each other in a first horizontal direction and extend along a first straight line in the first horizontal direction at a first vertical level over the circuit substrate, and the plurality of upper bit lines comprise an upper bit line connected to a first group of the plurality of upper vertical channel structures, and an upper connection bit line connected to the upper bit line, wherein the upper bit line connected to the first group of upper vertical channel structures is at a second vertical level and the upper connection bit line is at the first vertical level, and wherein the second vertical level is farther from the circuit substrate than the first vertical level.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments;

FIGS. 2A and 2B are each a schematic perspective view illustrating an example of a configuration of a memory cell array unit that is included in the semiconductor device shown in FIG. 1;

FIG. 3 is an equivalent circuit diagram of a memory cell array of a semiconductor device according to some embodiments;

FIG. 4 is a diagram illustrating a semiconductor device according to some embodiments;

FIG. 5 is a schematic plan view of a portion of a cell array structure that is included in a semiconductor device according to some embodiments;

FIG. 6 is a cross-sectional view illustrating in more detail a semiconductor device according to some embodiments;

FIG. 7A is a planar layout schematically illustrating some components of a semiconductor device according to some embodiments, and FIG. 7B is a schematic diagram illustrating connection relationships of a plurality of bit lines shown in FIG. 7A;

FIGS. 8, 9, and 10 are each a planar layout schematically illustrating some components of a semiconductor device according to some embodiments;

FIGS. 11A to 11I are cross-sectional views respectively illustrating a sequence of processes of a method of manufacturing a semiconductor device, according to some embodiments;

FIG. 12 is a diagram schematically illustrating an electronic system including a semiconductor device according to at least one embodiment; and

FIG. 13 is a perspective view schematically illustrating an electronic system including a semiconductor device according to at least one embodiment.

### DETAILED DESCRIPTION OF THE EMBODIMENTS

Hereinafter, embodiments of the inventive concepts will be described in detail with reference to the accompanying drawings. Like components are denoted by like reference numerals throughout the specification, and repeated descriptions thereof are omitted.

Additionally, in the present specification, functional elements and/or device, including units that have and/or configured to have at least one function or operation such a “functional device”, “controller” and/or “ . . . unit”, may be implemented with processing circuitry including hardware, software, or a combination of hardware and software. For example, the processing circuitry more specifically may include, but is not limited to, a central processing unit (CPU), a neural processing unit (NPU), a graphics processing unit (GPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In the drawings, thicknesses of layers and regions may be exaggerated for clarification of the specification. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

The following embodiments described below are merely illustrative, and various modifications may be possible from the embodiments of the present disclosure. When an element or layer is referred to as being “on” or “above” another element or layer, the element or layer may be directly on another element or layer or intervening elements or layers. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Similarly, although numerical terms such as “first,” “second,” “third,” etc., may be used herein to describe various elements, components, regions, layers, and/or sections, these elements, components, regions, layers, and/or sections, these terms are only used to distinguish one element, component, region, layer, or section, from another region, layer, or section. Thus, a first element, component, region, layer, or section, discussed below may be also be termed a second element, component, region, layer, or section, without departing from the scope of this disclosure.

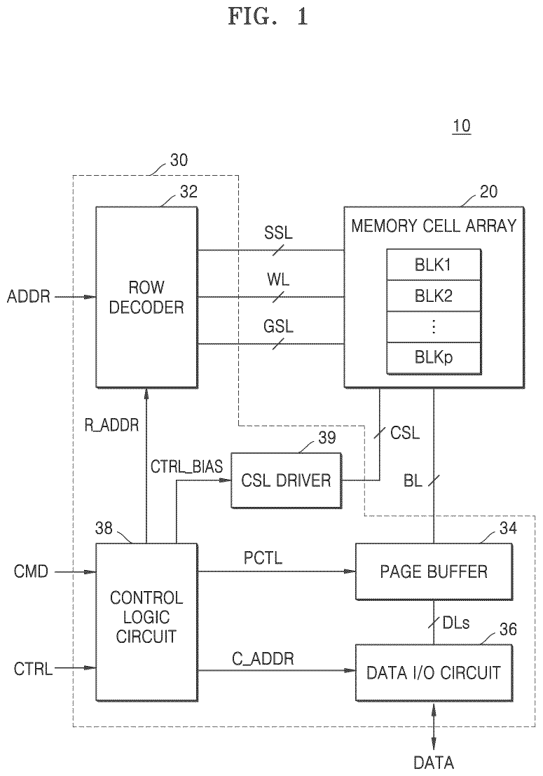

FIG. 1 is a block diagram of a semiconductor device 10 according to some embodiments.

Referring to FIG. 1, the semiconductor device 10 may include a memory cell array unit 20 and a peripheral circuit unit 30. The memory cell array unit 20 may include a plurality of memory cell blocks BLK1, BLK2, . . . , and BLKp. Each of the plurality of memory cell blocks BLK1, BLK2, . . . , and BLKp may include a plurality of memory cells. A memory cell block BLK1, BLK2, . . . , or BLKp may be connected to the peripheral circuit unit 30 via a bit line BL, a word line WL, a string select line SSL, and a ground select line GSL.

The peripheral circuit unit 30 may include a row decoder 32, a page buffer 34, a data input/output circuit 36, a control logic 38, and a common source line driver 39. The peripheral circuit unit 30 may further include various circuits, such as a voltage generation circuit for generating various voltages required for operations of the semiconductor device 10, an error correction circuit for correcting errors in data read from the memory cell array unit 20, an input/output interface configured to receive signal from and/or to output signals to outside the semiconductor device 10, and/or the like.

The memory cell array unit 20 may be connected to the row decoder 32 via the word line WL, the string select line SSL, and the ground select line GSL and may be connected to the page buffer 34 via the bit line BL. In the memory cell array unit 20, each of the plurality of memory cells, which are included in the plurality of memory cell blocks BLK1, BLK2, . . . , and BLKp, may include a flash memory cell. The memory cell array unit 20 may include a 3-dimensional memory cell array. The 3-dimensional memory cell array may include a plurality of NAND strings, and each of the plurality of NAND strings may include a plurality of memory cells respectively connected to a plurality of word lines WL that are vertically stacked.

The peripheral circuit unit 30 may be configured to receive an address ADDR, a command CMD, and a control signal CTRL from outside the semiconductor device 10 and to transmit data DATA to and receive data DATA from a device external to the semiconductor device 10.

The row decoder 32 may be configured to select at least one of the plurality of memory cell blocks BLK1, BLK2, . . . , and BLKp in response to the address ADDR from outside the semiconductor device 10 and may select the word line WL, the string select line SSL, and the ground select line GSL of the selected memory cell block. For example, the row decoder 32 may transfer a voltage for performing a memory operation to the word line WL of the selected memory cell block.

The page buffer 34 may be connected to the memory cell array unit 20 via the bit line BL. The page buffer 34 may be configured to apply a voltage according to the data DATA (which is to be stored in the memory cell array unit 20) to the bit line BL by operating as a write driver during a program operation and may sense the data DATA, which is stored in the memory cell array unit 20, by operating as a sense amplifier during a read operation. The page buffer 34 may operate according to a control signal PCTL provided by the control logic 38.

The data input/output circuit 36 may be connected with the page buffer 34 via a plurality of data lines DLs. During the program operation, the data input/output circuit 36 may be configured to receive the data DATA from a memory controller (not shown) and to provide program data DATA to the page buffer 34, based on a column address C_ADDR provided by the control logic 38. During the read operation, the data input/output circuit 36 may provide read data DATA stored in the page buffer 34 to the memory controller, based on the column address C_ADDR provided by the control logic 38.

The data input/output circuit 36 may be configured to transfer an address and/or a command, which is input thereto, to the control logic 38 or the row decoder 32. The peripheral circuit unit 30 may further include an electrostatic discharge (ESD) circuit and a pull-up/pull-down driver.

The control logic 38 may receive the command CMD and the control signal CTRL from the memory controller. The control logic 38 may be configured to provide a row address R_ADDR to the row decoder 32 and provide the column address C_ADDR to the data input/output circuit 36. The control logic 38 may generate various internal control signals, which are used in the semiconductor device 10, in response to the control signal CTRL. For example, when a memory operation, such as a program operation or an erase operation, is performed, the control logic 38 may adjust levels of voltages respectively provided to the word line WL and the bit line BL.

The common source line driver 39 may be connected to the memory cell array unit 20 via a common source line CSL. The common source line driver 39 may be configured to apply a common source voltage (for example, a power supply voltage) or a ground voltage to the common source line CSL, based on control by the control logic 38.

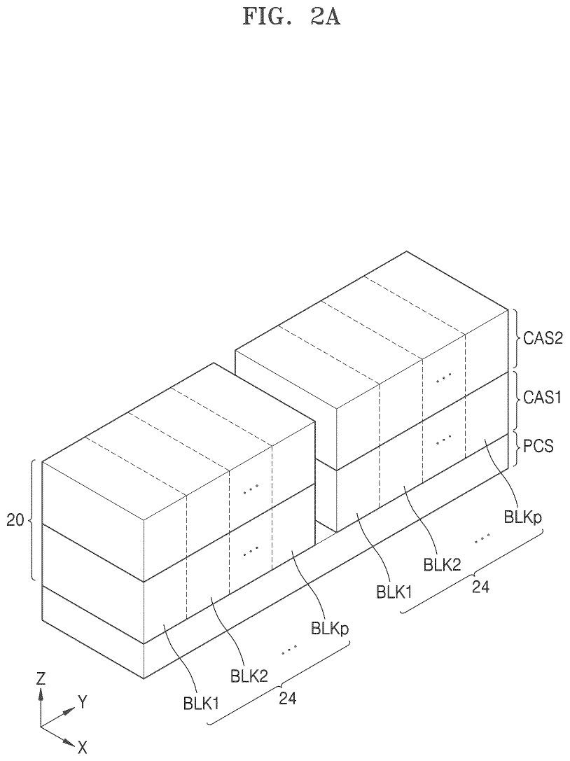

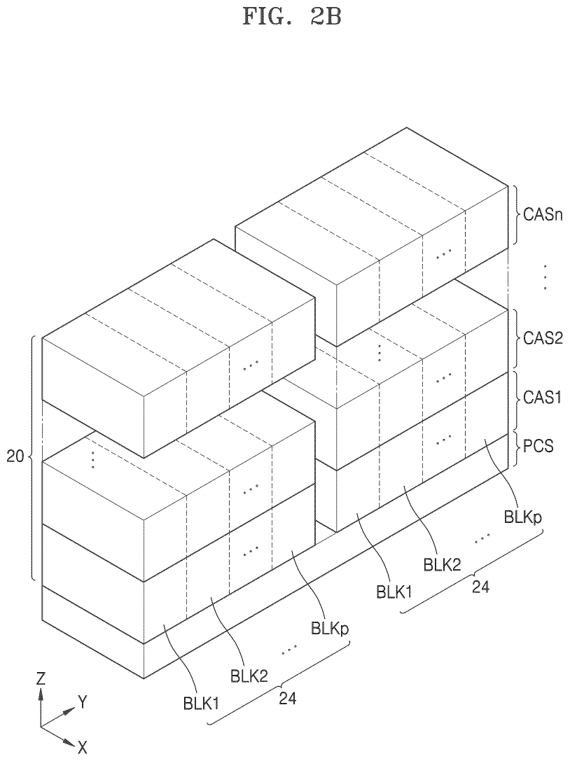

FIG. 2A is a schematic perspective view illustrating an example of a configuration of the memory cell array unit 20 that is included in the semiconductor device 10 shown in FIG. 1.

Referring to FIG. 2A, the memory cell array unit 20 of the semiconductor device 10 may include a first cell array structure CAS1 and a second cell array structure CAS2, which are stacked in the stated order in the vertical direction (the Z direction) on a peripheral circuit structure PCS to overlap the peripheral circuit structure PCS in the vertical direction (the Z direction).

The peripheral circuit structure PCS may include the peripheral circuit unit 30 described with reference to FIG. 1. For example, the peripheral circuit structure PCS may include the various circuits constituting the peripheral circuit unit 30 shown in FIG. 1. The second cell array structure CAS2 may be apart from the peripheral circuit structure PCS in the vertical direction (the Z direction) with the first cell array structure CAS1 therebetween. Each of the first cell array structure CAS1 and the second cell array structure CAS2 may be configured to be physically and electrically connectable to a plurality of circuits in the peripheral circuit structure PCS.

An electrical connection and data transmission may be made, via a plurality of connection structures, between the peripheral circuit structure PCS and the first cell array structure CAS1 and between the peripheral circuit structure PCS and the second cell array structure CAS2. The plurality of connection structures may provide a physical connection and an electrical connection between the peripheral circuit structure PCS and the first cell array structure CAS1 and between the peripheral circuit structure PCS and the second cell array structure CAS2. Each of the plurality of connection structures may include a connection unit including a metal-metal bonding structure, a through-silicon via (TSV), a back via stack (BVS), a eutectic bonding structure, a ball grid array (BGA) bonding structure, a plurality of wiring lines, a plurality of contact plugs, a combination thereof, and/or the like. In some embodiments, the metal-metal bonding structure may include, e.g., copper (Cu), aluminum (Al), tungsten (W), and/or a combination thereof.

Each of the first cell array structure CAS1 and the second cell array structure CAS2 may include a plurality of tiles 24. Each of the plurality of tiles 24 may include a plurality of memory cell blocks BLK1, BLK2, . . . , and BLKp. Each of the plurality of memory cell blocks BLK1, BLK2, . . . , and BLKp may include memory cells that are 3-dimensionally arranged. In each of the first cell array structure CAS1 and the second cell array structure CAS2, two tiles 24 may constitute one mat, but the inventive concepts are not limited thereto.

FIG. 2B is a schematic perspective view illustrating another example of the configuration of the memory cell array unit 20 that is included in the semiconductor device 10 shown in FIG. 1. In FIG. 2B, the same reference numerals as in FIGS. 1 and 2A respectively denote the same members, and here, repeated descriptions thereof are omitted.

Referring to FIG. 2B, the memory cell array unit 20 of the semiconductor device 10 may include a plurality of cell array structures (that is, CAS1, CAS2, . . . , and CASn), which are stacked in the stated order in the vertical direction (the Z direction) on the peripheral circuit structure PCS to overlap the peripheral circuit structure PCS in the vertical direction (the Z direction). The number of cell array structures (that is, CAS1, CAS2, . . . , and CASn) stacked in the vertical direction (the Z direction) on the peripheral circuit structure PCS is not particularly limited. For example, the number of cell array structures (that is, CAS1, CAS2, . . . , and CASn) stacked in the vertical direction (the Z direction) may be, but is not limited to, 3 to 10 (that is, n is an integer of 3 to 10).

Each of the plurality of cell array structures (that is, CAS1, CAS2, . . . , and CASn) may be configured to be physically and electrically connectable to a plurality of circuits in the peripheral circuit structure PCS. An electrical connection and data transmission may be made, via a plurality of connection structures, between the peripheral circuit structure PCS and each of the plurality of cell array structures (that is, CAS1, CAS2, . . . , and CASn). Detailed configurations of the plurality of connection structures are the same as those described with reference to FIG. 2A. A more detailed configuration of each of the plurality of cell array structures (that is, CAS1, CAS2, . . . , and CASn) is the same as that of each of the first cell array structure CAS1 and the second cell array structure CAS2 described with reference to FIG. 2A.

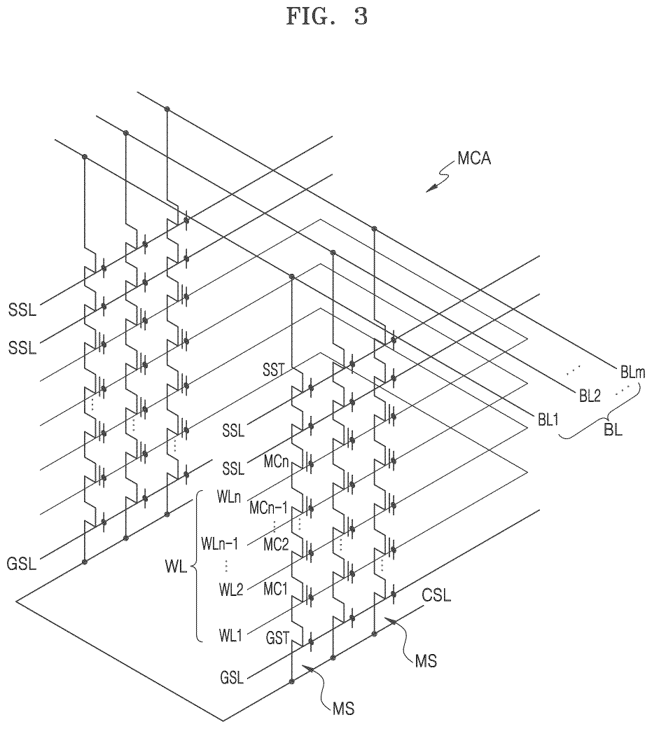

FIG. 3 is an equivalent circuit diagram of a memory cell array MCA of a semiconductor device according to some embodiments. FIG. 3 illustrates an equivalent circuit diagram of a vertical NAND flash memory device having a vertical channel structure. Each of the plurality of memory cell blocks BLK1, BLK2, . . . , and BLKp shown in FIGS. 1, 2A, and 2B may include a memory cell array MCA having a circuit configuration shown in FIG. 3.

Referring to FIG. 3, the memory cell array MCA may include a plurality of memory cell strings MS. The memory cell array MCA may include a plurality of bit lines BL (that is, BL1, BL2, . . . , and BLm), a plurality of word lines WL (that is, WL1, WL2, . . . , WLn−1, and WLn), at least one string select line SSL, at least one ground select line GSL, and a common source line CSL. The plurality of memory cell strings MS may be formed between the plurality of bit lines BL and the common source line CSL. Although FIG. 3 illustrates an example in which each of the plurality of memory cell strings MS includes one ground select line GSL and two string select lines SSL, the inventive concepts are not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn−1, and MCn. A drain region of the string select transistor SST may be connected to a bit line BL, and a source region of the ground select transistor GST may be connected to the common source line CSL. The common source line CSL may be a region to which source regions of a plurality of ground select transistors GST are commonly connected.

The string select transistor SST may be connected to the string select line SSL, and the ground select transistor GST may be connected to the ground select line GSL. Each of the plurality of memory cell transistors MC1, MC2, . . . , MCn−1, and MCn may be connected to a word line WL.

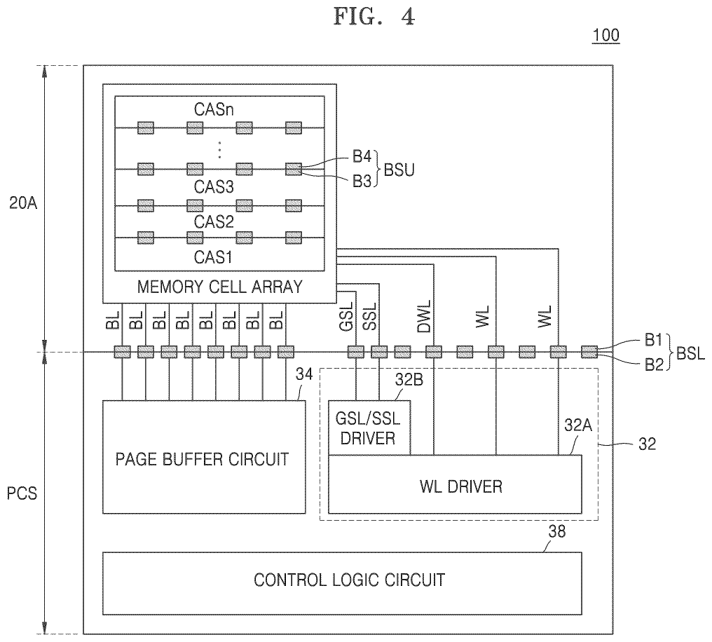

FIG. 4 is a diagram illustrating a semiconductor device 100 according to some embodiments. In FIG. 4, the same reference numerals as in FIGS. 1, 2A, and 2B respectively denote the same members, and thereby, repeated descriptions thereof may be omitted.

Referring to FIG. 4, the semiconductor device 100 may include a peripheral circuit structure PCS and a memory cell array unit 20A on the peripheral circuit structure PCS. The memory cell array unit 20A may include the plurality of cell array structures (that is, CAS1, CAS2, . . . , and CASn) shown in FIG. 2B. However, this is only an example, and the memory cell array unit 20A may include the first cell array structure CAS1 and the second cell array structure CAS2, which are shown in FIG. 2A. The memory cell array unit 20A may correspond to the memory cell array unit 20 shown in FIG. 1.

In the memory cell array unit 20A, each of the plurality of cell array structures (that is, CAS1, CAS2, . . . , and CASn) may include a plurality of bit lines BL, a ground select line GSL, a string select line SSL, a plurality of word lines WL, and a dummy word line DWL. The memory cell array unit 20A may include a plurality of first bonding pads B1, which are respectively connected to the plurality of bit lines BL, the ground select line GSL, the string select line SSL, the plurality of word lines WL, and the dummy word line DWL. The respective numbers of bit lines BL and word lines WL, which are connected to the plurality of cell array structures (that is, CAS1, CAS2, . . . , and CASn), may be variously changed depending on embodiments, and thus, the number of first bonding pads B1 in the memory cell array unit 20A may also be variously changed depending on embodiments.

The peripheral circuit structure PCS may include at least some of the row decoder 32, the page buffer 34, and the control logic 38, which are included in the peripheral circuit unit 30 described with reference to FIG. 1. The row decoder 32 may include a word line driver 32A and a ground select line/string select line driver 32B. The peripheral circuit structure PCS may further include a voltage generator, an input/output circuit, and/or the like. The peripheral circuit structure PCS may include a plurality of second bonding pads B2, which are respectively arranged at positions corresponding to the plurality of first bonding pads B1. A bonding structure of a first bonding pad B1 and a second bonding pad B2 may constitute a lower bonding structure BSL.

Among the plurality of second bonding pads B2, some second bonding pads B2 may be connected between the plurality of bit lines BL and the page buffer 34, some other second bonding pads B2 may be connected between both of the plurality of word lines WL and the dummy word line DWL and the word line driver 32A, and yet some other second bonding pads B2 may be connected between both of the ground select line GSL and the string select line SSL and the ground select line/string select line driver 32B.

A plurality of bonding structures including a plurality of third bonding pads B3 and a plurality of fourth bonding pads B4 may be arranged between each of the plurality of cell array structures (that is, CAS1, CAS2, . . . , and CASn). The plurality of fourth bonding pads B4 may be respectively arranged at positions corresponding to the plurality of third bonding pads B3. A bonding structure of a third bonding pad B3 and a fourth bonding pad B4 may constitute an upper bonding structure BSU.

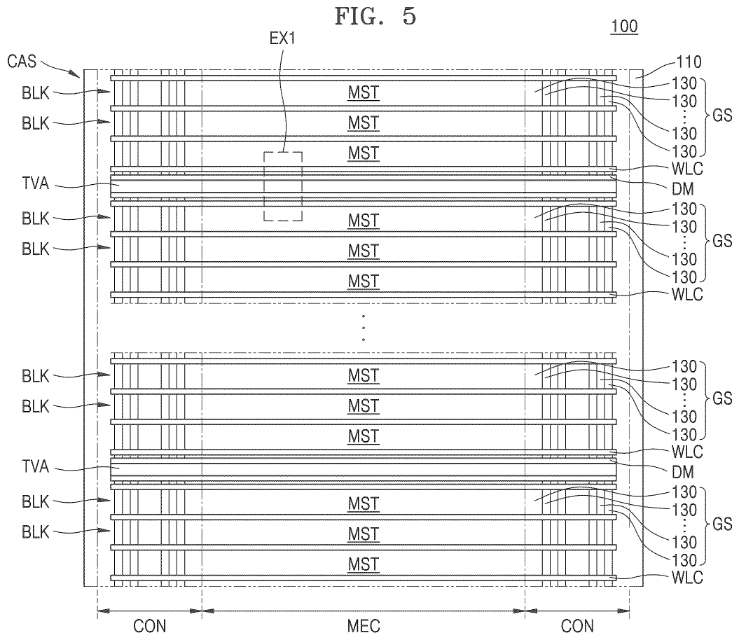

FIG. 5 is a schematic plan view of a portion of a cell array structure CAS that is included in the semiconductor device 100 according to some embodiments. The cell array structure CAS shown in FIG. 5 may correspond to a cell array structure closest to the peripheral circuit structure PCS, among a plurality of cell array structures stacked in the vertical direction (the Z direction) on the peripheral circuit structure PCS in the semiconductor device 100, for example, a first cell array structure CAS1 closest to the peripheral circuit structure PCS, among the plurality of cell array structures (that is, CAS1, CAS2, . . . , and CASn) shown in FIG. 4.

Referring to FIG. 5, the cell array structure CAS of the semiconductor device 100 may include an upper substrate 110 and a plurality of memory cell blocks BLK on the upper substrate 110. The plurality of memory cell blocks BLK may correspond to the plurality of memory cell blocks BLK1, BLK2, . . . , and BLKp described with reference to FIGS. 2A and 2B.

The peripheral circuit structure PCS (see FIGS. 2A, 2B, and 4) may be arranged under the upper substrate 110. The plurality of memory cell blocks BLK may be arranged to overlap the peripheral circuit structure PCS in the vertical direction (the Z direction) with the upper substrate 110 therebetween. Each of the plurality of memory cell blocks BLK may have a plane shape extending lengthwise in the first horizontal direction (the X direction), in the viewpoint of a plane (the X-Y plane in FIG. 5).

The cell array structure CAS may include a memory cell area MEC and a connection area CON on both sides of the memory cell area MEC in terms of the first horizontal direction (the X direction). Each of the plurality of memory cell blocks BLK may include a memory stack structure MST extending in the first horizontal direction (the X direction) throughout the memory cell area MEC and the connection area CON. The memory stack structure MST may include a plurality of gate lines 130 stacked over the upper substrate 110 in the memory cell area MEC and the connection area CON to overlap each other in the vertical direction (the Z direction). In each of a plurality of memory stack structures MST, the plurality of gate lines 130 may constitute a gate stack GS. In each of the plurality of memory stack structures MST, the plurality of gate lines 130 may respectively constitute the ground select line GSL, the plurality of word lines WL, and the string select line SSL, which are shown in FIG. 3. Each of the plurality of gate lines 130 may have a gradually decreasing area in the X-Y plane with an increasing distance from the upper substrate 110. A central portion of each of the plurality of gate lines 130 overlapping each other in the vertical direction (the Z direction) may constitute the memory cell area MEC, and an edge portion of each of the plurality of gate lines 130 may constitute the connection area CON.

A plurality of word line cut structures WLC may be arranged on the upper substrate 110 to extend lengthwise in the first horizontal direction (the X direction) in the memory cell area MEC and the connection area CON. The plurality of word line cut structures WLC may be arranged apart from each other in the second horizontal direction (the Y direction). Herein, the second horizontal direction (the Y direction) may be a direction intersecting with the first horizontal direction (the X direction), for example, a direction orthogonal to the first horizontal direction (the X direction). The plurality of memory cell blocks BLK may be respectively arranged one-by-one between the plurality of word line cut structures WLC. The plurality of word line cut structures WLC may be respectively arranged one-by-one on both sides of each of the plurality of memory cell blocks BLK in terms of the second horizontal direction (the Y direction) to define the width of each of the plurality of memory cell blocks BLK in the second horizontal direction (the Y direction).

The semiconductor device 100 may include a plurality of through-contact regions TVA, which pass through the cell array structure CAS in the vertical direction (the Z direction). The plurality of through-contact regions TVA may each be arranged between two adjacent memory cell blocks BLK selected from the plurality of memory cell blocks BLK. A dam structure DM may be arranged on both sides of each of the plurality of through-contact regions TVA in terms of the second horizontal direction (the Y direction). The width of each of the plurality of through-contact regions TVA in the second horizontal direction (the Y direction) may be defined by a pair of dam structures DM respectively arranged on both sides of a through-contact region TVA in terms of the second horizontal direction (the Y direction). The dam structure DM may include an insulating film, for example, a silicon oxide film. The plurality of through-contact regions TVA and a plurality of dam structures DM around the plurality of through-contact regions TVA may each extend lengthwise in the first horizontal direction (the X direction).

Although FIG. 5 illustrates two through-contact regions TVA passing through the cell array structure CAS in the vertical direction (the Z direction), the inventive concepts is not limited thereto. For example, although three, five, or seven through-contact regions TVA may be arranged through one cell array structure CAS, the inventive concepts is not limited thereto.

The peripheral circuit structure PCS under the upper substrate 110 may include the peripheral circuit unit 30 described with reference to FIG. 1. In some embodiments, the page buffer 34 (see FIGS. 1 and 4) among the plurality of circuits of the peripheral circuit structure PCS may be arranged to overlap the plurality of through-contact regions TVA in the vertical direction (the Z direction).

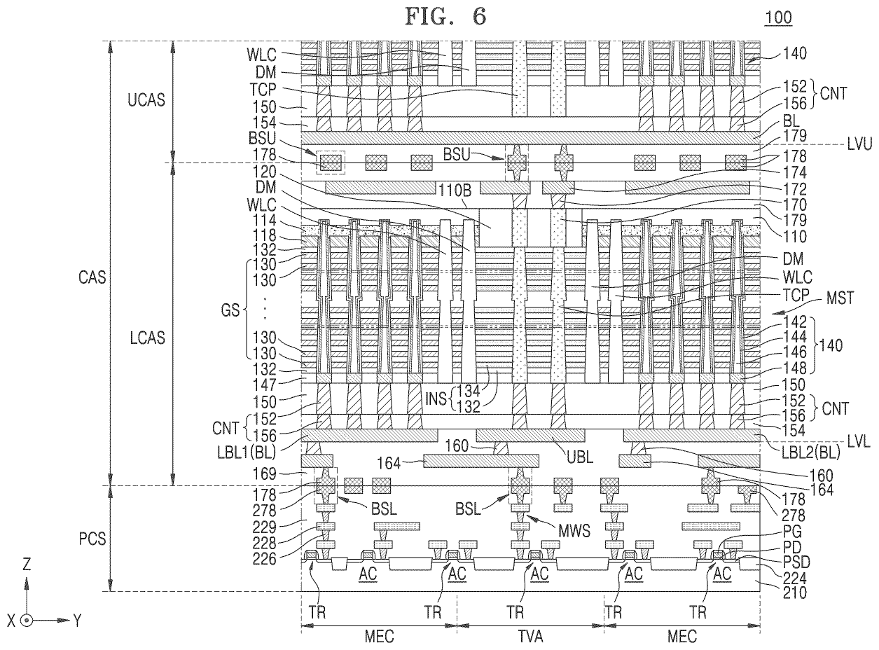

FIG. 6 is a cross-sectional view illustrating the semiconductor device 100 according to some embodiments in more detail. FIG. 6 illustrates a peripheral circuit structure PCS and a plurality of cell array structures CAS arranged on the peripheral circuit structure PCS to overlap the peripheral circuit structure PCS in the vertical direction (the Z direction). In FIG. 6, the same reference numerals as in FIGS. 1 to 5 respectively denote the same members, and here, repeated descriptions thereof are omitted.

Herein, a cell array structure CAS closest to the peripheral circuit structure PCS, from among the plurality of cell array structures CAS shown in FIG. 6, may be referred to as a lower cell array structure LCAS, and a cell array structure CAS apart from the peripheral circuit structure PCS in the vertical direction (the Z direction) with the lower cell array structure LCAS therebetween, from among the plurality of cell array structures CAS, may be referred to as an upper cell array structure UCAS.

Referring to FIG. 6, the semiconductor device 100 includes the peripheral circuit structure PCS, and the plurality of cell array structures CAS arranged on the peripheral circuit structure PCS and overlapping the peripheral circuit structure PCS in the vertical direction (the Z direction). FIG. 6 illustrates respective portions of the lower cell array structure LCAS closest to the peripheral circuit structure PCS and the upper cell array structure UCAS apart from the peripheral circuit structure PCS in the vertical direction (the Z direction) with the lower cell array structure LCAS therebetween, among the plurality of cell array structures CAS.

The peripheral circuit structure PCS may include a circuit substrate 210, a plurality of circuits on the circuit substrate 210, and a multilayer wiring structure MWS for connecting the plurality of circuits to each other or connecting the plurality of circuits to components in the plurality of cell array structures CAS.

In the peripheral circuit structure PCS, the circuit substrate 210 may include a semiconductor substrate. For example, the circuit substrate 210 may include an elemental semiconductor such as Si, Ge, or SiGe and/or a compound semiconductor such as SiC, GaN, and/or the like. An active region AC may be defined in the circuit substrate 210 by a device isolation film 224. A plurality of transistors TR, which constitute the plurality of circuits, may be formed on the active region AC. Each of the plurality of transistors TR may include a gate PG and a plurality of ion-implanted regions PSD formed in the active region AC on both sides of the gate PG. Each of the plurality of ion-implanted regions PSD may constitute a source region or a drain region of a transistor TR.

The plurality of circuits of the peripheral circuit structure PCS may include various circuits that are included in the peripheral circuit unit 30 described with reference to FIG. 1. In some embodiments, the plurality of circuits of the peripheral circuit structure PCS may include the row decoder 32, the page buffer 34, the data input/output circuit 36, the control logic 38, and the common source line driver 39, which are shown in FIG. 1.

The multilayer wiring structure MWS of the peripheral circuit structure PCS may include a plurality of peripheral circuit contacts 226 and a plurality of wiring layers 228. At least some of the plurality of wiring layers 228 may be configured to be electrically connected to the transistors TR. The plurality of peripheral circuit contacts 226 may be configured to respectively connect the plurality of transistors TR to some selected from the plurality of wiring layers 228.

A plurality of conductive components, for example, the plurality of word lines WL and the plurality of bit lines BL, which are included in the plurality of cell array structures CAS, may each be configured to be connected to at least one circuit selected from the plurality of circuits via the multilayer wiring structure MWS of the peripheral circuit structure PCS. Although FIG. 6 illustrates an example in which the multilayer wiring structure MWS has three wiring layers 228 in the vertical direction (the Z direction), the inventive concepts is not limited to the example shown in FIG. 6. For example, the multilayer wiring structure MWS may include two wiring layers 228 or four or more wiring layers 228.

Each of the plurality of peripheral circuit contacts 226 and the plurality of wiring layers 228 may include a metal, a conductive metal nitride, a metal silicide, or a combination thereof. For example, each of the plurality of peripheral circuit contacts 226 and the plurality of wiring layers 228 may include a conductive material, such as tungsten, molybdenum, titanium, cobalt, tantalum, nickel, tungsten silicide, titanium silicide, cobalt silicide, tantalum silicide, or nickel silicide.

The plurality of transistors TR and the multilayer wiring structure MWS, which are included in the peripheral circuit structure PCS, may be covered by an interlayer dielectric 229. The interlayer dielectric 229 may include silicon oxide, SiON, SiOCN, and/or the like.

The lower cell array structure LCAS may include an upper substrate 110, and a first conductive plate 114, a second conductive plate 118, and a memory stack structure MST, which are stacked in the stated order on the upper substrate 110 in the memory cell array MEC. The first conductive plate 114 and the second conductive plate 118 may function as the common source line CSL described with reference to FIG. 3. The first conductive plate 114 and the second conductive plate 118 may function as a source region for supplying currents to vertical memory cells that are included in the cell array structure CAS. The upper substrate 110, the first conductive plate 114, and the second conductive plate 118 may be apart from the peripheral circuit structure PCS in the vertical direction (the Z direction) with the memory stack structure MST therebetween.

In some embodiments, the upper substrate 110 may include a semiconductor material, such as polysilicon. Each of the first conductive plate 114 and the second conductive plate 118 may include a doped polysilicon film, a metal film, or a combination thereof. The metal film may include, but is not limited to, tungsten (W). The memory stack structure MST may include a gate stack GS. The gate stack GS may include a plurality of gate lines 130 extending parallel to each other in a horizontal direction (the X direction and the Y direction in FIG. 6) and overlapping each other in the vertical direction (the Z direction). Each of the plurality of gate lines 130 may include a metal, a metal silicide, an impurity-doped semiconductor, or a combination thereof. For example, each of the plurality of gate lines 130 may include a metal, such as tungsten, nickel, cobalt, or tantalum, a metal silicide, such as tungsten silicide, nickel silicide, cobalt silicide, or tantalum silicide, doped polysilicon, or a combination thereof.

An insulating film 132 may be arranged between the second conductive plate 118 and the plurality of gate lines 130 and between each of the plurality of gate lines 130. A gate line 130 farthest from the upper substrate 110, among the plurality of gate lines 130, may be covered by the insulating film 132. The insulating film 132 may include silicon oxide.

A plurality of word line cut structures WLC may be arranged on the upper substrate 110 in the memory cell area MEC. Each of the plurality of word line cut structures WLC may extend lengthwise in the first horizontal direction (the X direction). The width of each of the plurality of gate lines 130 in the second horizontal direction (the Y direction) may be defined by the plurality of word line cut structures WLC. Each of the plurality of word line cut structures WLC may include an insulating structure. In some embodiments, the insulating structure may include silicon oxide, silicon nitride, silicon oxynitride, or a low-k dielectric material. For example, the insulating structure may include a silicon oxide film, a silicon nitride film, an SiON film, an SiOCN film, an SiCN film, and/or a combination thereof. In some embodiments, at least a portion of the insulating structure may include an air gap. As used herein, the term “air” may refer to the atmosphere or to other gases that may be present during a manufacturing process.

The plurality of gate lines 130 constituting one gate stack GS may be stacked on the second conductive plate 118 between two adjacent word line cut structures WLC to overlap each other in the vertical direction (the Z direction). The plurality of gate lines 130 constituting one gate stack GS may include the ground select line GSL, the plurality of word lines WL, and the string select line SSL, which are described with reference to FIG. 3.

Some selected from the plurality of gate lines 130, for example, two gate lines 130, may be separated from each other in the second horizontal direction (the Y direction) with a string select line cut structure therebetween. Each of the two gate lines 130 separated from each other with the string select line cut structure therebetween may constitute the string select line SSL described with reference to FIG. 3. The string select line cut structure may include an insulating film. In some embodiments, the string select line cut structure may include an insulating film including, e.g., an oxide film, a nitride film, and/or a combination thereof.

A plurality of vertical channel structures 140 may be arranged on the upper substrate 110 in the memory cell area MEC. The plurality of vertical channel structures 140 may be arranged between the peripheral circuit structure PCS and the upper substrate 110 to extend lengthwise in the vertical direction (the Z direction) through the plurality of gate lines 130, a plurality of insulating films 132, the second conductive plate 118, and the first conductive plate 114. The plurality of vertical channel structures 140 may be arranged at certain intervals in the first horizontal direction (the X direction) and the second horizontal direction (the Y direction) to be apart from each other. Each of the plurality of vertical channel structures 140 may include a gate dielectric film 142, a channel region 144, a buried insulating film 146, and a drain region 148.

The gate dielectric film 142 may include a tunneling dielectric film, a charge storage film, and a blocking dielectric film, which are sequentially formed in the stated order on the channel region 144. The tunneling dielectric film may include, e.g., silicon oxide, hafnium oxide, aluminum oxide, zirconium oxide, tantalum oxide, and/or the like. The charge storage film is a region, in which electrons having passed through the tunneling dielectric film from the channel region 144 may be stored, and may include, e.g., silicon nitride, boron nitride, silicon boron nitride, or impurity-doped polysilicon. The blocking dielectric film may include, e.g., silicon oxide, silicon nitride, or a metal oxide having a dielectric constant that is greater than that of silicon oxide. The metal oxide may include, for example, hafnium oxide, aluminum oxide, zirconium oxide, tantalum oxide, and/or a combination thereof.

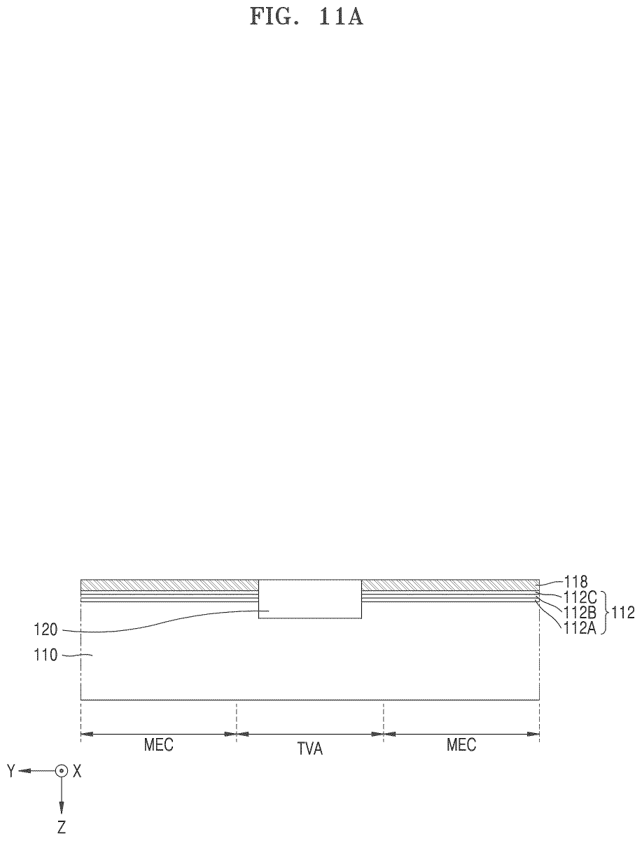

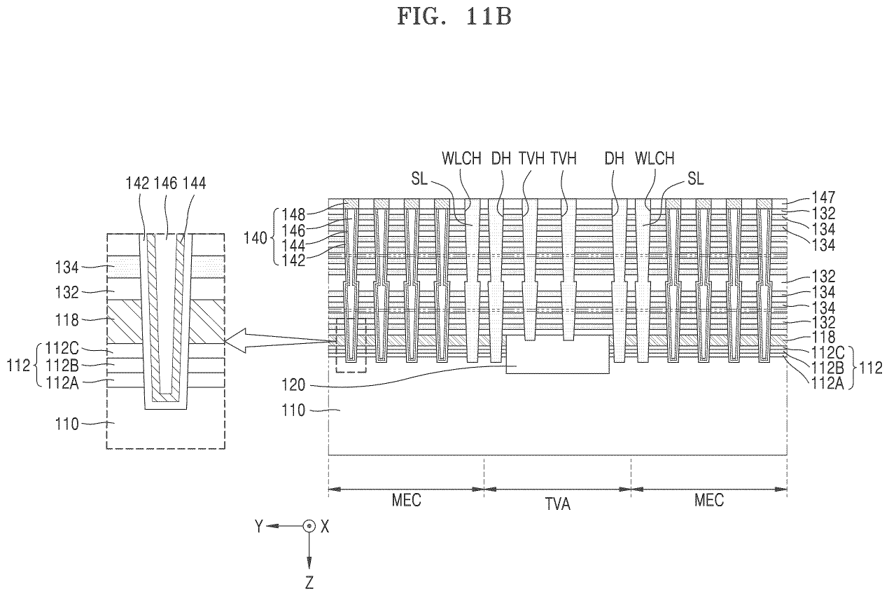

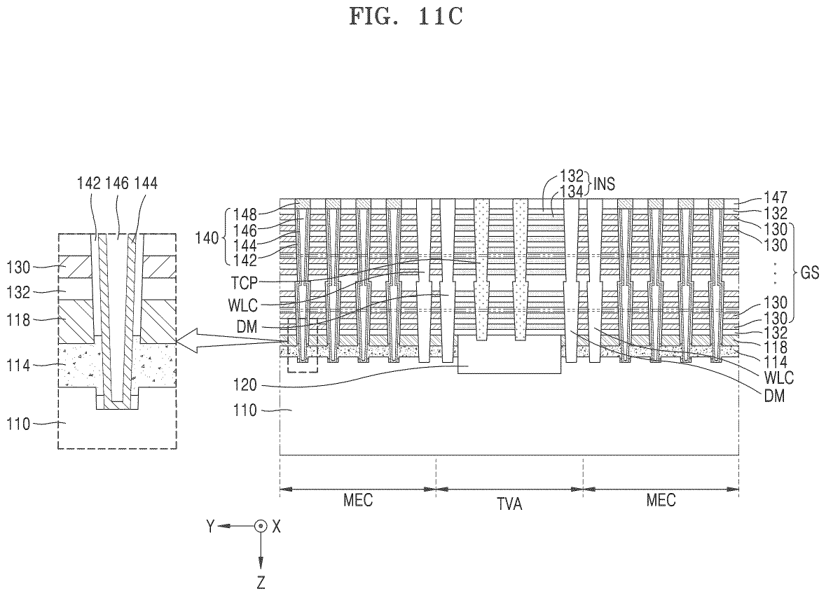

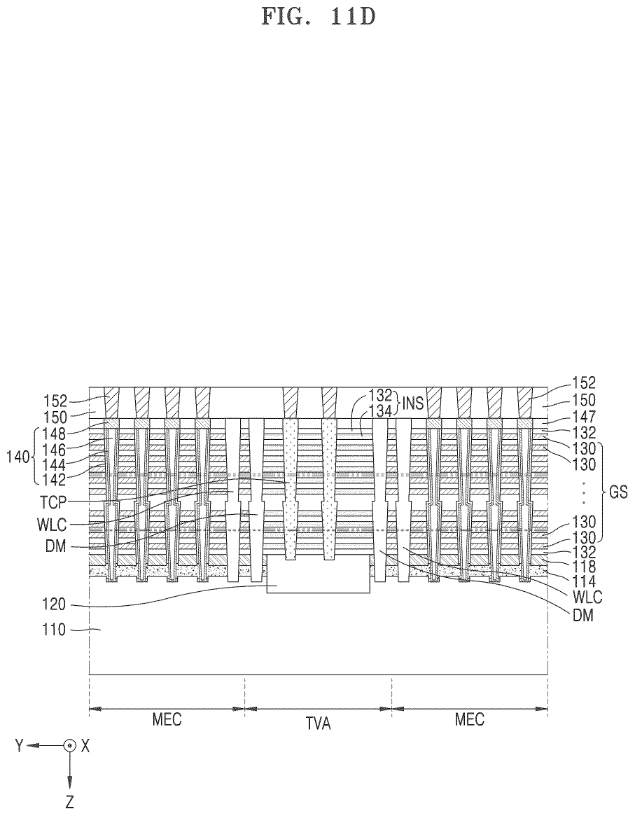

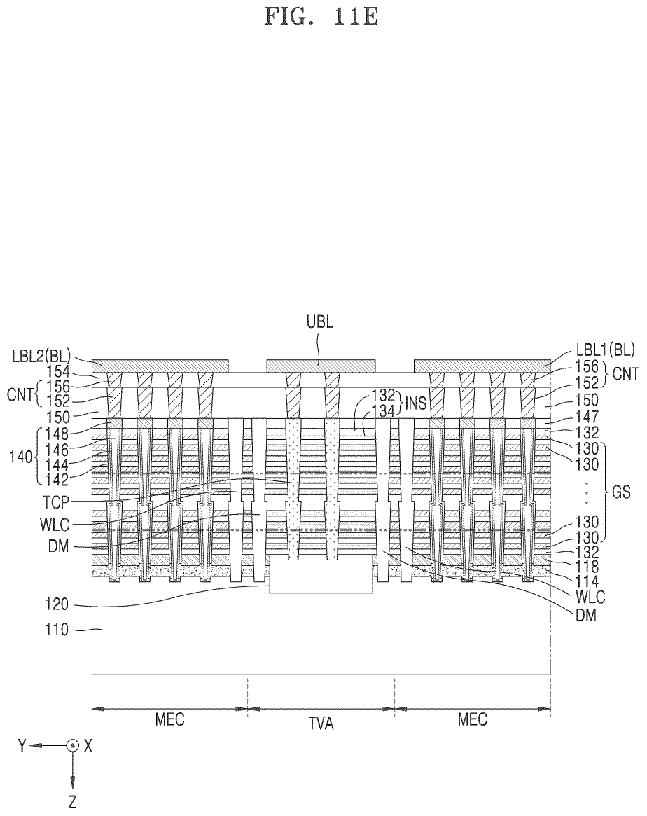

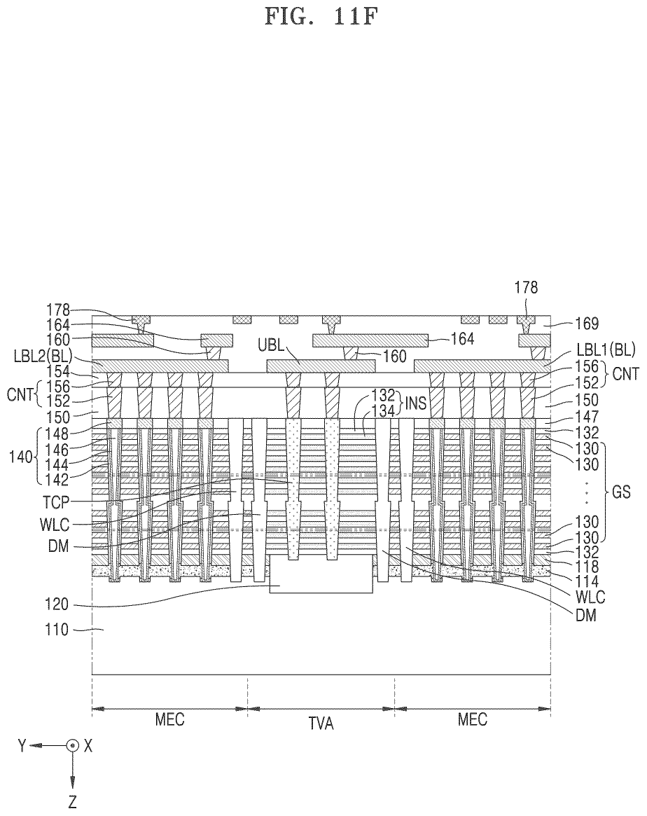

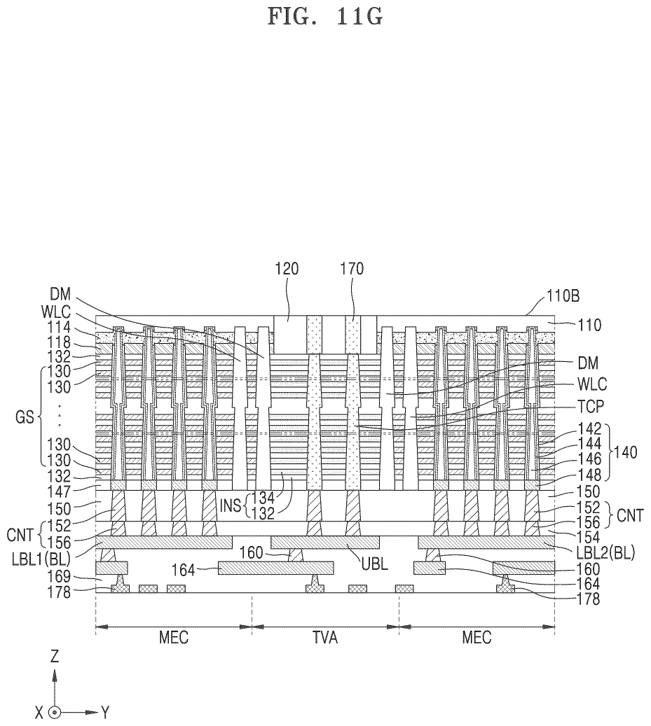

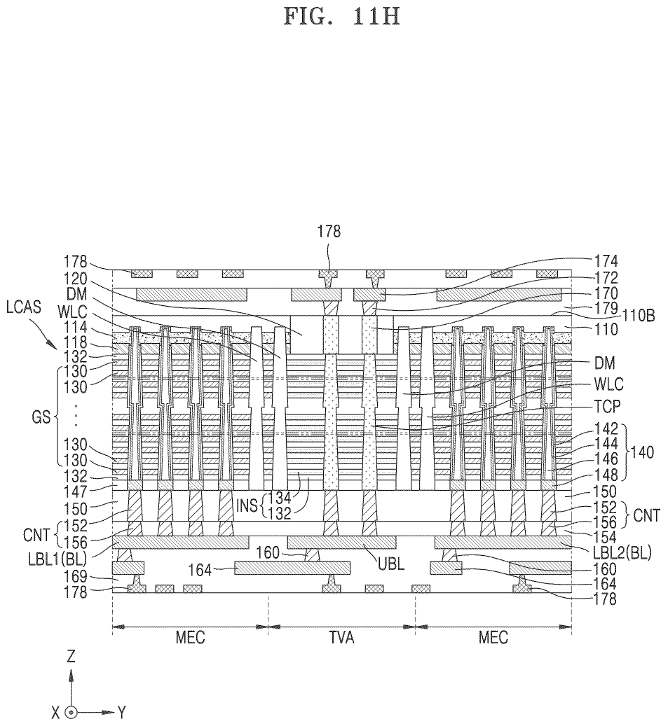

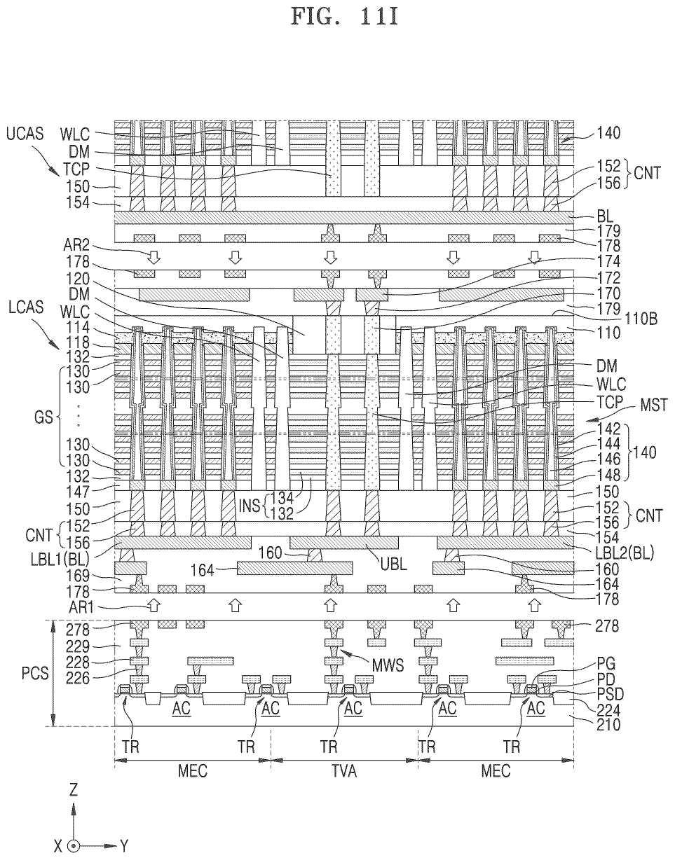

The first conductive plate 114 may pass through a portion of the gate dielectric film 142 in the horizontal direction (the X direction and/or the Y direction) to contact the channel region 144, as shown in the enlarged cross-sectional view of FIG. 11C. The thickness (the Z-direction size) of a portion of the first conductive plate 114, which vertically overlaps the gate dielectric film 142, may be greater than the thickness (the Z-direction size) of a portion of the first conductive plate 114, which vertically overlaps the second conductive plate 118. The channel region 144 may be apart from the upper substrate 110 with a portion of the gate dielectric film 142 therebetween. The sidewall of the channel region 144 may be in contact with the first conductive plate 114 and may be configured to be electrically connected to the first conductive plate 114.

As shown in FIG. 6, the channel region 144 may have a cylindrical shape. The channel region 144 may include doped polysilicon or undoped polysilicon. The buried insulating film 146 may fill an inner space of the channel region 144. The buried insulating film 146 may include an insulating material. For example, the buried insulating film 146 may include silicon oxide, silicon nitride, silicon oxynitride, or a combination thereof. In some embodiments, the buried insulating film 146 may be omitted. In these cases, the channel region 144 may have a pillar structure having no inner space. The drain region 148 may include doped polysilicon. A plurality of drain regions 148 may be insulated from each other by an upper insulating film 147.

In a portion of the memory cell area MEC, an insulating plug 120 may be arranged to pass through the upper substrate 110, the first conductive plate 114, and the second conductive plate 118 in the vertical direction (the Z direction), and a plurality of conductive plugs 170 may pass through the insulating plug 120 in the vertical direction (the Z direction).

An insulating structure INS and a pair of dam structures DM may pass through the lower cell array structure LCAS in the vertical direction (the Z direction) and may extend lengthwise in the first horizontal direction (the X direction). The insulating structure INS may be arranged in an area defined by the pair of dam structures DM. In the area defined by the pair of dam structures DM, the plurality of through-contact plugs TCP may pass through the insulating structure INS in the vertical direction (the Z direction). In the memory stack structure MST, an area in which the insulating plug 120, the plurality of conductive plugs 170, and the pair of dam structures DM are arranged may be defined as a through-contact region TVA.

The insulating plug 120 may be arranged in an area overlapping the insulating structure INS in the vertical direction (the Z direction). The insulating plug 120 may include a silicon oxide film, a silicon nitride film, or a combination thereof. One end of each of the plurality of through-contact plugs TCP may be in contact with one conductive plug 170 selected from the plurality of conductive plugs 170.

The insulating structure INS may be apart from the plurality of gate lines 130 with a dam structure DM and a word line cut structure WLC therebetween. The insulating structure INS may include a multilayered insulating film in which an insulating film 132 and a sacrificial insulating film 134 are alternately stacked a plurality of times. In the insulating structure INS, the insulating film 132 may include a silicon oxide film and the sacrificial insulating film 134 may include a silicon nitride film. In some embodiments, the insulating structure INS may include a single insulating film. In the through-contact region TVA defined by the dam structures DM, a surface of the insulating structure INS, which faces the peripheral circuit structure PCS, may be covered by a first interlayer dielectric 150 and a second interlayer dielectric 154. Each of the first interlayer dielectric 150 and the second interlayer dielectric 154 may include, but is not limited to, a silicon oxide film.

The memory stack structure MST may include a plurality of first connection plugs 152, which pass through the first interlayer dielectric 150 in the vertical direction (the Z direction), and a plurality of second connection plugs 156, which pass through the second interlayer dielectric 154 in the vertical direction (the Z direction).

The memory stack structure MST may include a plurality of bit lines BL, which are arranged on the second interlayer dielectric 154, and a plurality of contact plugs 160 and a plurality of wiring layers 164, which are arranged on or over the plurality of bit lines BL. Each of the plurality of bit lines BL may be connected to the drain region 148 of the vertical channel structure 140 via a first connection plug 152 and a second connection plug 156.

Some of the respective surfaces of the plurality of contact plugs 160 and the plurality of wiring layers 164 may be covered by a third interlayer dielectric 169. A wiring structure including the plurality of contact plugs 160, the plurality of wiring layers 164, and the third interlayer dielectric 169 may be arranged between the plurality of bit lines BL and the peripheral circuit structure PCS.

In the lower cell array structure LCAS, a wiring structure including a plurality of contact plugs 172, a plurality of wiring layers 174, and a fourth interlayer dielectric 179 may be arranged on a backside surface 110B of the upper substrate 110. One end of each of the plurality of conductive plugs 170, which faces the upper cell array structure UCAS, may be in contact with one contact plug 172 selected from the plurality of contact plugs 172 and may be connected to one wiring layer 174 selected from the plurality of wiring layers 174 via the one contact plug 172.

The upper cell array structure UCAS may have substantially the same structure as the lower cell array structure LCAS described above. The upper cell array structure UCAS may overlap the peripheral circuit structure PCS in the vertical direction (the Z direction) with the lower cell array structure LCAS therebetween. Herein, the vertical channel structure 140 in the lower cell array structure LCAS may be referred to as a lower vertical channel structure, and the vertical channel structure 140 in the upper cell array structure UCAS may be referred to as an upper vertical channel structure. In addition, herein, the bit line BL in the lower cell array structure LCAS may be referred to as a lower bit line, and the bit line BL in the upper cell array structure UCAS may be referred to as an upper bit line.

The plurality of bit lines BL of the lower cell array structure LCAS may include a first lower bit line LBL1 connected to a first group of vertical channel structures 140, which are selected from the plurality of vertical channel structures 140, and a second lower bit line LBL2 connected to a second group of vertical channel structures 140, which are selected from the plurality of vertical channel structures 140 and are apart from the first group of vertical channel structures 140. In the lower cell array structure LCAS, each of the first lower bit line LBL1 and the second lower bit line LBL2, which are adjacent to each other, may be arranged on an imaginary first straight line extending in the second horizontal direction (the Y direction) at a first vertical level LVL above the circuit substrate 210 of the peripheral circuit structure PCS and may extend lengthwise in the second horizontal direction (the Y direction). The first lower bit line LBL1 and the second lower bit line LBL2, which are adjacent to each other, may be apart from each other in the second horizontal direction (the Y direction).

The plurality of bit lines BL of the upper cell array structure UCAS may be arranged at a second vertical level LVU that is farther from the circuit substrate 210 than the first vertical level LVL. The plurality of bit lines BL of the upper cell array structure UCAS may include a bit line BL (which may be referred to as an upper bit line) connected to a first group of vertical channel structures 140, which are selected from the plurality of vertical channel structures 140 of the upper cell array structure UCAS, and an upper connection bit line UBL arranged at the first vertical level LVL and configured to be connected to the bit line BL of the upper cell array structure UCAS. Although the upper connection bit line UBL functionally constitutes the upper cell array structure UCAS, the upper connection bit line UBL may be physically located at the same vertical level as the lower cell array structure LCAS.

The upper connection bit line UBL may be arranged between the first lower bit line LBL1 and the second lower bit line LBL2 on the imaginary first straight line at the first vertical level LVL and may be apart from the first lower bit line LBL1 and the second lower bit line LBL2 in the second horizontal direction (the Y direction).

In the lower cell array structure LCAS, the first lower bit line LBL1 may be connected to the first group of vertical channel structures 140 selected from the plurality of vertical channel structures 140 of the lower cell array structure LCAS, the second lower bit line LBL2 may be connected to the second group of vertical channel structures 140 selected from the plurality of vertical channel structures 140 of the lower cell array structure LCAS, and the upper connection bit line UBL may not be connected to any of the plurality of vertical channel structures 140 of the lower cell array structure LCAS. In the lower cell array structure LCAS, the first group of vertical channel structures 140 may be apart from the second group of vertical channel structures 140 in the second horizontal direction (the Y direction) with the insulating structure INS and the plurality of through-contact plugs TCP therebetween, the insulating structure INS and the plurality of through-contact plugs TCP being arranged in the through-contact region TVA.

The upper connection bit line UBL may be configured to be connected to the bit line BL of the upper cell array structure UCAS via at least one through-contact plug TCP, which is selected from the plurality of through-contact plugs TCP arranged in the through-contact region TVA, and at least one conductive plug 170, which is selected from the plurality of conductive plugs 170.

The first lower bit line LBL1 and the second lower bit line LBL2 may be configured to be connected to each other through one wiring layer 164 selected from the plurality of wiring layers 164 arranged between the peripheral circuit structure PCS and the lower cell array structure LCAS. Each of the first lower bit line LBL1, the second lower bit line LBL2, and the upper connection bit line UBL may be configured to be connected to at least one circuit selected from the plurality of circuits of the peripheral circuit structure PCS via one wiring layer 164 selected from the plurality of wiring layers 164. For example, each of the first lower bit line LBL1, the second lower bit line LBL2, and the upper connection bit line UBL may be configured to be connected to the page buffer 34 (see FIGS. 1 and 4) that is included in the peripheral circuit structure PCS. The bit line BL of the upper cell array structure UCAS may be configured to be connected to the page buffer 34 (see FIGS. 1 and 4) of the peripheral circuit structure PCS, via at least one through-contact plug TCP, which is selected from the plurality of through-contact plugs TCP, the upper connection bit line UBL, and one of the wiring layers 164, which is selected from the plurality of wiring layers 164. The wiring layer 164, which is connected to the first lower bit line LBL1 and the second lower bit line LBL2, among the plurality of wiring layers 164 is one wiring layer 164 and may be referred to herein as a first wiring layer. The wiring layer 164, which is connected to the upper connection bit line UBL, among the plurality of wiring layers 164 is another wiring layer separated from the first wiring layer and may be referred to herein as a second wiring layer.

In some embodiments, the plurality of through-contact plugs TCP, the plurality of bit lines BL, the plurality of first connection plugs 152, the plurality of second connection plugs 156, the plurality of conductive plugs 170, the plurality of contact plugs 160, the plurality of wiring layers 164, the plurality of contact plugs 172, and the plurality of wiring layers 174 may each include, but are not limited to, tungsten, titanium, tantalum, copper, aluminum, titanium nitride, tantalum nitride, tungsten nitride, or a combination thereof. Each of the first to fourth interlayer dielectrics 150, 154, 169, and 179 may include, but is not limited to, a silicon oxide film.

As shown in FIG. 6, the plurality of through-contact plugs TCP passing through a portion of the upper cell array structure UCAS in the vertical direction (the Z direction) may not connected to the bit line BL of the upper cell array structure UCAS. However, some of the plurality of through-contact plugs TCP passing through another portion of the upper cell array structure UCAS in another area not shown in FIG. 6 may each be configured to be connected to the bit line BL of the upper cell array structure UCAS. Each of the lower cell array structure LCAS and the upper cell array structure UCAS may include a plurality of through-contact regions TVA that are apart from each other as described with reference to FIG. 5, and all bit lines BL of the upper cell array structure UCAS may each be connected to a circuit of the peripheral circuit structure PCS via the through-contact plug TCP and the upper connection bit line UBL connected to the through-contact plug TCP, the through-contact plug TCP being arranged in one through-contact region TVA selected from the plurality of through-contact regions TVA of the lower cell array structure LCAS.

A plurality of lower bonding structures BSL may be arranged between the plurality of wiring layers 164 of the lower cell array structure LCAS and the peripheral circuit structure PCS, and a plurality of upper bonding structures BSU may be arranged between the lower cell array structure LCAS and the upper cell array structure UCAS. Each of the plurality of lower bonding structures BSL may include a first bonding metal pad 178, which is included in the lower cell array structure LCAS, and a second bonding metal pad 278, which is included in the peripheral circuit structure PCS. Each of the plurality of upper bonding structures BSU may include a pair of first bonding metal pads 178 respectively included in the lower cell array structure LCAS and the upper cell array structure UCAS. A plurality of first bonding metal pads 178 and a plurality of second bonding metal pads 278 may each include, but are not limited to, copper, aluminum, or tungsten.

The bit line BL of the upper cell array structure UCAS may be connected to the wiring layer 174 of the lower cell array structure LCAS via the plurality of upper bonding structures BSU and may be connected to the upper connection bit line UBL by sequentially passing through the upper bonding structure BSU, the wiring layer 174, the contact plug 172, the conductive plug 170, the through-contact plug TCP, the first connection plug 152, and the second connection plug 156 in the stated order. The bit line BL of the upper cell array structure UCAS may be configured to be connected to a circuit, for example, the page buffer 34 (see FIGS. 1 and 4), which is included in the peripheral circuit structure PCS, via the upper bonding structure BSU, the upper connection bit line UBL, the wiring layer 164, and the lower bonding structure BSL.

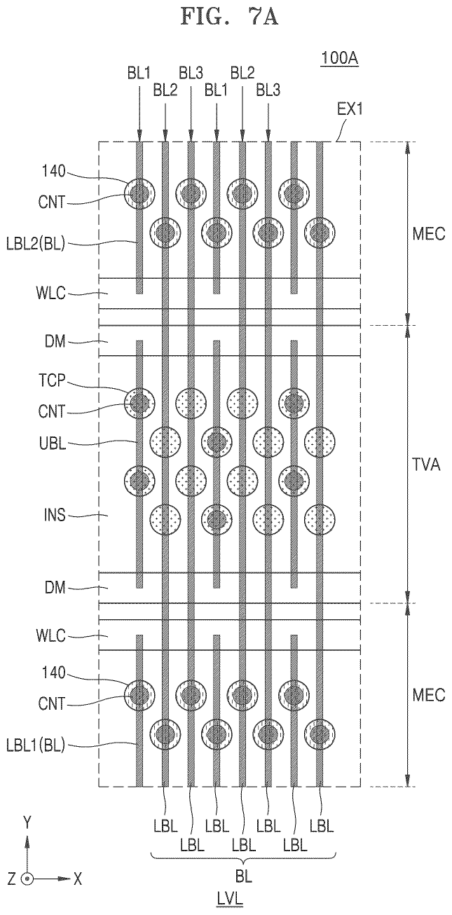

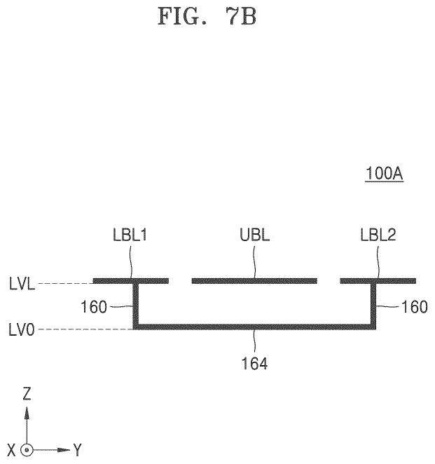

FIG. 7A is a planar layout schematically illustrating some components of a semiconductor device 100A according to some embodiments, and FIG. 7B is a schematic diagram illustrating connection relationships of a plurality of bit lines shown in FIG. 7A. FIG. 7A illustrates some components in a portion of the semiconductor device 100A, which corresponds to the region EX1 of FIG. 5. In FIGS. 7A and 7B, the same reference numerals as in FIGS. 1 to 6 respectively denote the same members, and here, repeated descriptions thereof are omitted.

Referring to FIG. 7A, the semiconductor device 100A may have substantially the same configuration as the semiconductor device 100 described with reference to FIG. 6. In the viewpoint of a plane (the X-Y plane in FIG. 7A), the size of each of the plurality of through-contact plugs TCP arranged in the through-contact region TVA may be equal or similar to the size of each of the plurality of vertical channel structures 140 arranged in the memory cell area MEC. In addition, in a constant unit planar area, the density of the plurality of through-contact plugs TCP arranged in the through-contact region TVA may be equal or similar to the density of the plurality of vertical channel structures 140 arranged in the memory cell area MEC. The plurality of through-contact plugs TCP arranged in the through-contact region TVA may form a hexagonal array, and the plurality of vertical channel structures 140 arranged in the memory cell area MEC may form a hexagonal array.

The plurality of bit lines BL may extend lengthwise in the second horizontal direction (the Y direction) at the first vertical level LVL above the circuit substrate 210 (see FIG. 6) of the peripheral circuit structure PCS. The plurality of bit lines BL arranged at the first vertical level LVL may include the first lower bit line LBL1 and the second lower bit line LBL2, which are apart from each other with the through-contact region TVA therebetween. The upper connection bit line UBL may be arranged in the through-contact region TVA between the first lower bit line LBL1 and the second lower bit line LBL2 and may be apart from each of the first lower bit line LBL1 and the second lower bit line LBL2 in the second horizontal direction (the Y direction). The first lower bit line LBL1, the upper connection bit line UBL, and the second lower bit line LBL2 may arranged on an imaginary first straight line extending in the second horizontal direction (the Y direction).

The upper connection bit line UBL may be connected to, via a connection structure CNT, at least one through-contact plug TCP selected from the plurality of through-contact plugs TCP arranged in the through-contact region TVA. In some embodiments, the connection structure CNT may include the first connection plug 152 and the second connection plug 156, which are shown in FIG. 6.

Each of the plurality of bit lines BL of the lower cell array structure LCAS may not be connected to the plurality of through-contact plugs TCP arranged in the through-contact region TVA. In the plurality of bit lines BL of the lower cell array structure LCAS, one bit line BL selected every three bit lines BL in terms of the first horizontal direction (the X direction) may have a smaller length in the second horizontal direction (the Y direction) than the other bit lines BL and thus may not overlap the through-contact region TVA in the vertical direction (the Z direction). When three bit lines BL consecutively arranged in the first horizontal direction (the X direction) in the plurality of bit lines BL of the lower cell array structure LCAS are taken as one bit line group, as shown in FIG. 7A, a first bit line BL1 selected from each of a plurality of bit line groups may have a smaller length in the second horizontal direction (the Y direction) than the other bit lines BL and thus may not overlap the through-contact region TVA in the vertical direction (the Z direction), and a second bit line BL2 and a third bit line BL3 may each extend lengthwise in the second horizontal direction (the Y direction) and thus may overlap the through-contact region TVA in the vertical direction (the Z direction).

As shown in FIG. 7B, the first lower bit line LBL1 and the second lower bit line LBL2 may be connected to each other via a wiring layer 164 and a plurality of contact plugs 160, the wiring layer 164 being arranged at a vertical level LV0 that is closer to the peripheral circuit structure PCS than the first vertical level LVL.

As described with reference to FIG. 5, when the semiconductor device 100A includes a plurality of through-contact regions TVA passing through the cell array structure CAS in the vertical direction (the Z direction), in the through-contact region TVA shown in FIG. 7A and areas adjacent to the through-contact region TVA, the first bit line BL1 selected from each of the plurality of bit line groups may have a smaller length than the second bit line BL2 and the third bit line BL3 and thus may not overlap the through-contact region TVA in the vertical direction (the Z direction), and in another through-contact region TVA, which is apart from the through-contact region TVA shown in FIG. 7A in the second horizontal direction (the Y direction), and areas adjacent to the other through-contact region TVA, the second bit line BL2 selected from each of the plurality of bit line groups may have a smaller length than the first bit line BL1 and the third bit line BL3 and thus may not overlap the other through-contact region TVA in the vertical direction (the Z direction). In this case, the upper connection bit line UBL, which is arranged at the first vertical level LVL and configured to be connected to the bit line BL of the upper cell array structure UCAS, and the second bit line BL2 may be arranged on a straight line in the second horizontal direction (the Y direction). Similarly, in yet another through-contact region TVA, which is apart from the through-contact region TVA shown in FIG. 7A in the second horizontal direction (the Y direction), and areas adjacent to the yet other through-contact region TVA, the third bit line BL3 selected from each of the plurality of bit line groups may have a smaller length than the first bit line BL1 and the second bit line BL2 and thus may not overlap the yet other through-contact region TVA in the vertical direction (the Z direction). In these cases, the upper connection bit line UBL, which is arranged at the first vertical level LVL and configured to be connected to the bit line BL of the upper cell array structure UCAS, and the third bit line BL3 may be arranged on a straight line in the second horizontal direction (the Y direction).

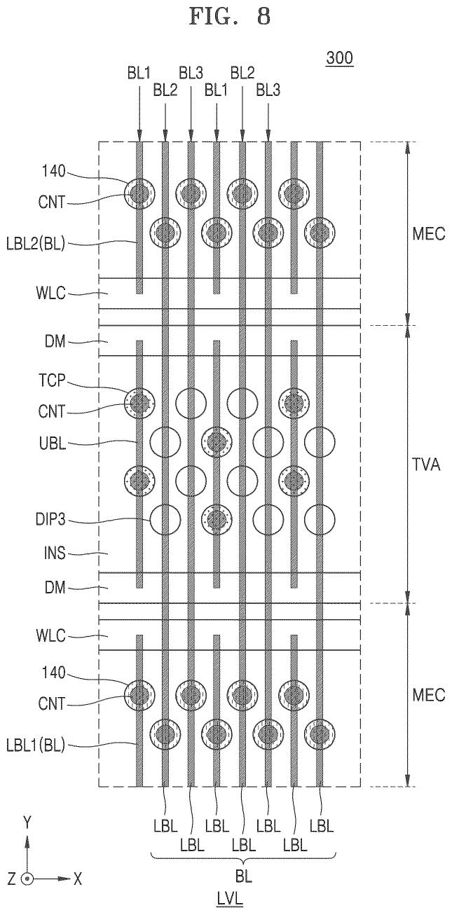

FIGS. 8, 9, and 10 are planar layouts schematically illustrating some components of semiconductor devices 300, 400, and 500 according to some embodiments, respectively. FIGS. 8, 9, and 10 each illustrate some components in a portion of each of the semiconductor devices 300, 400, and 500, which corresponds to the region EX1 of FIG. 5. In FIGS. 8, 9, and 10, the same reference numerals as in FIGS. 1 to 7B respectively denote the same members, and here, repeated descriptions thereof are omitted.

Referring to FIG. 8, the semiconductor device 300 may have substantially the same configuration as the semiconductor device 100A described with reference to FIGS. 7A and 7B. However, the semiconductor device 300 may further include a plurality of dummy insulating plugs DIP3 passing through the insulating structure INS in the vertical direction (the Z direction). Each of the plurality of dummy insulating plugs DIP3 may include, but is not limited to, a silicon oxide film, a silicon nitride film, or a combination thereof. The plurality of dummy insulating plugs DIP3 may be arranged to form a hexagonal array together with the plurality of through-contact plugs TCP.

When three bit lines BL consecutively arranged in the first horizontal direction (the X direction) in the plurality of bit lines BL of the lower cell array structure LCAS are taken as one bit line group, each of the second bit line BL2 and the third bit line BL3 selected from each of the plurality of bit line groups may extend lengthwise in the second horizontal direction (the Y direction) to overlap, in the vertical direction (the Z direction), at least one dummy insulating plug DIP3 selected from the plurality of dummy insulating plugs DIP3.

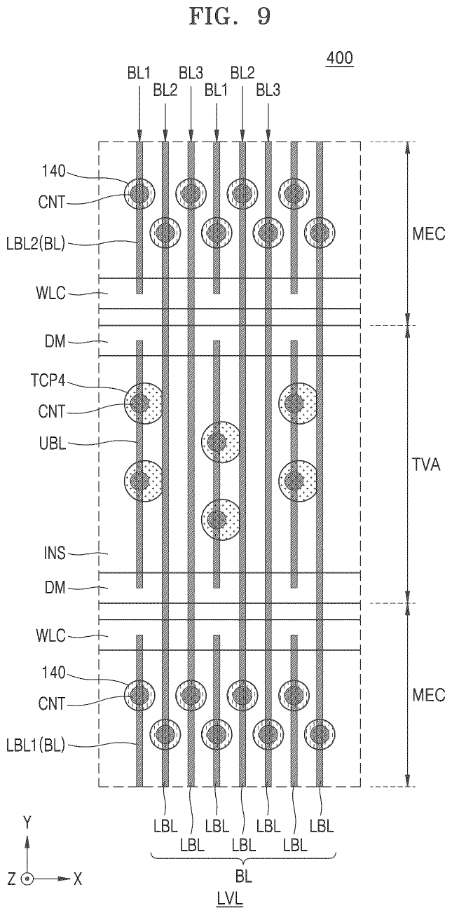

Referring to FIG. 9, the semiconductor device 400 may have substantially the same configuration as the semiconductor device 100A described with reference to FIGS. 7A and 7B. However, the semiconductor device 400 may further include a plurality of through-contact plugs TCP4 passing through the insulating structure INS in the vertical direction (the Z direction).

The plurality of through-contact plugs TCP4 may have substantially the same and/or a substantially similar configuration as the plurality of through-contact plugs TCP described with reference to FIG. 6. However, in the viewpoint of a plane (the X-Y plane in FIG. 9), the size of each of the plurality of through-contact plugs TCP4 may be greater than the size of each of the plurality of vertical channel structures 140, and in a constant unit planar area, the density of the plurality of through-contact plugs TCP4 may be less than the density of the plurality of vertical channel structures 140.

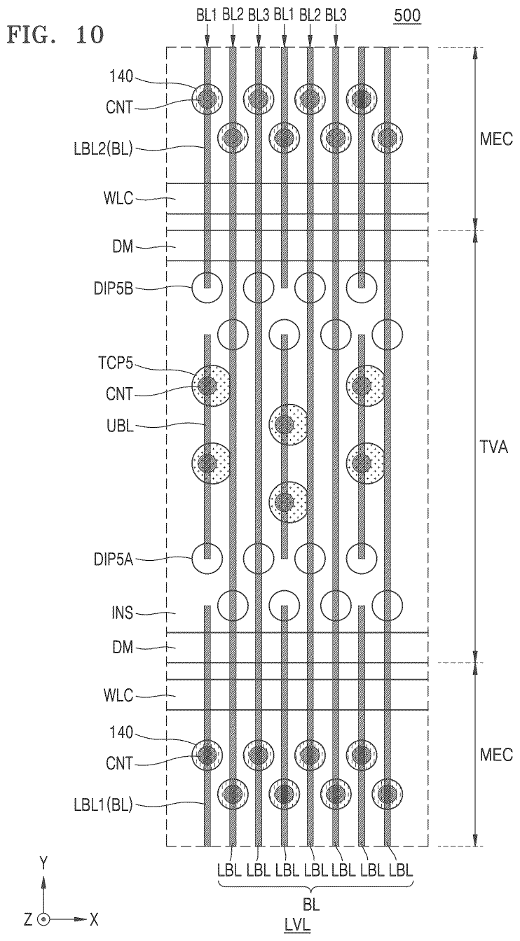

Referring to FIG. 10, the semiconductor device 500 may have substantially the same and/or a substantially similar configuration as the semiconductor device 400 described with reference to FIG. 9. However, the semiconductor device 500 may further include a plurality of through-contact plugs TCP5, which pass through the insulating structure INS in the vertical direction (the Z direction), and a plurality of dummy insulating plugs (that is, DIP5A and DIP5B), which pass through the insulating structure INS in the vertical direction (the Z direction).

The plurality of through-contact plugs TCP5 may have substantially the same (and/or a substantially similar) configuration as the plurality of through-contact plugs TCP4 described with reference to FIG. 9. The plurality of dummy insulating plugs (that is, DIP5A and DIP5B) may include a plurality of first dummy insulating plugs DIP5A, which pass through the insulating structure INS in the vertical direction (the Z direction) in a first local area between the plurality of through-contact plugs TCP5 and the first group of vertical channel structures 140, and a plurality of second dummy insulating plugs DIP5B, which pass through the insulating structure INS in the vertical direction (the Z direction) in a second local area between the plurality of through-contact plugs TCP5 and the second group of vertical channel structures 140. Each of the plurality of dummy insulating plugs (that is, DIP5A and DIP5B) may include, but is not limited to, a silicon oxide film, a silicon nitride film, or a combination thereof.

When three bit lines BL consecutively arranged in the first horizontal direction (the X direction) in the plurality of bit lines BL of the lower cell array structure LCAS are taken as one bit line group, the first bit line BL1 selected from each of the plurality of bit line groups may have a smaller length in the second horizontal direction (the Y direction) than the other bit lines BL and thus may not overlap the through-contact region TVA in the vertical direction (the Z direction), and each of the second bit line BL2 and the third bit line BL3 may pass over at least one first dummy insulating plug DIP5A, which is selected from the plurality of first dummy insulating plugs DIP5A, or an upper portion of at least one second dummy insulating plug DIP5B, which is selected from the plurality of second dummy insulating plugs DIP5B, and thus may overlap the at least one first dummy insulating plug DIP5A or the at least one second dummy insulating plug DIP5B in the vertical direction (the Z direction).

According to each of the semiconductor devices 100, 100A, 300, 400, and 500 described with reference to FIGS. 4 to 10, in a stack structure in which a plurality of cell array structures CAS each including 3-dimensionally arranged memory cells overlap each other in the vertical direction (the Z direction), the difference in length between a wiring line for connecting the bit line BL of the lower cell array structure LCAS from among the plurality of cell array structures CAS to a circuit, for example, the page buffer 34, of the peripheral circuit structure PCS and a wiring line for connecting the bit line BL of the upper cell array structure UCAS to the page buffer 34 may be minimized and/or reduced. Therefore, according to the inventive concepts, the semiconductor devices 100, 100A, 300, 400, and 500, which each have a structure advantageous for the improvement of the degree of integration by arranging 3-dimensionally arranged memory cells to overlap each other in the vertical direction, and which each have improved reliability by minimizing (and/or reducing) the difference in operation speed between each of the plurality of cell array structures CAS, may be provided.

FIGS. 11A to 11I are cross-sectional views respectively illustrating a sequence of processes of a method of manufacturing a semiconductor device, according to some embodiments. An example of a method of manufacturing the semiconductor device 100 described with reference to FIGS. 3 to 6 is described with reference to FIGS. 11A to 11I. In FIGS. 11A to 11I, the same reference numerals as in FIGS. 1 to 6 respectively denote the same members, and here, repeated descriptions thereof are omitted.

Referring to FIG. 11A, in the memory cell area MEC and the through-contact region TVA, an insulating plate 112 and the second conductive plate 118 may be formed in the stated order on the upper substrate 110. The insulating plate 112 may include an insulating film having a multilayered structure that includes a first insulating film 112A, a second insulating film 112B, and a third insulating film 112C.

Next, in the through-contact region TVA, a through-hole may be formed through a portion of the upper substrate 110, the insulating plate 112, and the second conductive plate 118, and the insulating plug 120 may be formed to fill the through-hole.

Referring to FIG. 11B, an intermediate structure may be formed, wherein the intermediate structure includes a stack structure in which a plurality of insulating films 132 and a plurality of sacrificial insulating films 134 are alternately formed one-by-one on the second conductive plate 118 and the insulating plug 120 in the memory cell area MEC and the through-contact region TVA, the upper insulating film 147 covering the stack structure, the vertical channel structure 140 and a plurality of word line cut holes WLCH, which pass through the stack structure and the upper insulating film 147 in the memory cell area MEC, a plurality of dam holes DH defining the through-contact region TVA, and a plurality of through-contact holes TVH passing through the stack structure and the upper insulating film 147 in the through-contact region TVA. Next, in the intermediate structure, a plurality of sacrificial films SL may be formed to fill the plurality of word line cut holes WLCH and the plurality of through-contact holes TVH. A process of forming the intermediate structure may be performed by various methods by using various processes well known in the art. Each of the plurality of sacrificial films SL may include, but is not limited to, a silicon oxide film.

In at least one embodiment, the plurality of insulating films 132 may each include a silicon oxide film, and the plurality of sacrificial insulating films 134 may each include a silicon nitride film. Portions of the plurality of sacrificial insulating films 134, which are in the memory cell area MEC, may respectively secure spaces for forming the plurality of gate lines 130 in a subsequent process.

Referring to FIG. 11C, in the resulting product of FIG. 11B, the plurality of dam holes DH may be emptied by removing the sacrificial film SL filling the inside of each of the plurality of dam holes DH that define the through-contact region TVA, and then filling the inside of each of the plurality of dam holes DH with the dam structure DM.

Next, the word line cut hole WLCH may be emptied by removing the sacrificial film SL filling the inside of each of the plurality of word line cut holes WLCH in the memory cell area MEC while a plurality of dam structures DM and the upper insulating film 147 each exposed in the through-contact region TVA are covered by a mask pattern, and then, the plurality of sacrificial insulating films 134 and the insulating plate 112, which are exposed by the plurality of word line cut holes WLCH, may be removed. Next, the first conductive plate 114 may be formed in a space from which the insulating plate 112 is removed, and the plurality of gate lines 130 may be respectively formed in spaces from which the plurality of sacrificial insulating films 134 are removed.

While the insulating plate 112 is being removed through the plurality of word line cut holes WLCH in the memory cell area MEC, portions, which are adjacent to the insulating plate 112, of the gate dielectric film 142 that is included in the vertical channel structure 140 in the memory cell area MEC may be removed together with the insulating plate 112, and as a result, the first conductive plate 114 may pass through a portion of the gate dielectric film 142 in the horizontal direction to contact the channel region 144.

While the insulating plate 112 and the plurality of sacrificial insulating films 134 are being removed through the plurality of word line cut holes WLCH, respective portions of the insulating plate 112 and the plurality of sacrificial insulating films 134, which are located in the through-contact region TVA surrounded by the dam structure DM, may be protected by the dam structure DM and thus may remain without being removed. The plurality of insulating films 132 and the plurality of sacrificial insulating films 134, which remain in the through-contact region TVA, may constitute the insulating structure INS. After the first conductive plate 114 and the plurality of gate lines 130 are formed, the plurality of word line cut holes WLCH may be respectively filled with the plurality of word line cut structures WLC.

Next, the mask pattern covering the plurality of dam structures DM and the upper insulating film 147 in the through-contact region TVA may be removed, followed by removing the plurality of sacrificial films SL, which respectively fill the plurality of through-contact holes TVH in the through-contact region TVA, and then, the through-contact plug TCP may fill the inside of each of the plurality of through-contact holes TVH.

Referring to FIG. 11D, the first interlayer dielectric 150 may be formed on the resulting product of FIG. 11C, and the plurality of first connection plugs 152 may be formed through the first interlayer dielectric 150. Here, the plurality of first connection plugs 152 may be formed such that some of the plurality of first connection plugs 152 are each connected to the drain region 148 of the vertical channel structure 140 and some others of the plurality of first connection plugs 152 are each connected to the through-contact plug TCP.

Referring to FIG. 11E, the second interlayer dielectric 154 and the plurality of second connection plugs 156, which pass through the second interlayer dielectric 154, may be formed on the resulting product of FIG. 11D, and the plurality of bit lines BL may be formed on the second interlayer dielectric 154 and the plurality of second connection plugs 156. The first connection plug 152 and the second connection plug 156 may constitute the connection structure CNT.

The plurality of bit lines BL may include the first lower bit line LBL1 connected to the first group of vertical channel structures 140 selected from the plurality of vertical channel structures 140, the second lower bit line LBL2 connected to the second group of vertical channel structures 140, which are selected from the plurality of vertical channel structures 140 and are apart from the first group of vertical channel structures 140, and the upper connection bit line UBL arranged in an area that is located between the first lower bit line LBL1 and the second lower bit line LBL2 and vertically overlaps the through-contact region TVA.

Referring to FIG. 11F, a wiring structure, which includes the plurality of contact plugs 160, the plurality of wiring layers 164, and the third interlayer dielectric 169, may be formed on the resulting product of FIG. 11D, followed by removing a plurality of local contact regions from the exposed upper surface of the third interlayer dielectric 169, and then, the plurality of first bonding metal pads 178 may be respectively formed in the plurality of local contact regions.

Referring to FIG. 11G, the resulting product of FIG. 11F is placed such that the upper substrate 110 faces upwards in the vertical direction (the Z direction), followed by reducing the thickness of the upper substrate 110 by removing the upper substrate 110 by as much as a certain thickness from the exposed backside surface 110B of the upper substrate 110, thereby exposing the insulating plug 120 by the backside surface 110B having a reduced thickness. For example, the thickness of the upper substrate 110 may be reduced through planarization, chemical-mechanical polishing, etc. Next, the plurality of conductive plugs 170 may be formed to pass through the insulating plug 120 in the vertical direction (the Z direction) and to respectively contact the plurality of through-contact plugs TCP one-to-one.

Referring to FIG. 11H, in the resulting product of FIG. 11G, a wiring structure, which includes the plurality of contact plugs 172, the plurality of wiring layers 174, and the fourth interlayer dielectric 179, may be formed on the insulating plug 120 and the backside surface 110B of the upper substrate 110 having a reduced thickness. One end of each of the plurality of conductive plugs 170 may be in contact with one contact plug 172 selected from the plurality of contact plugs 172. Next, a plurality of local contact regions may be removed from the exposed upper surface of the fourth interlayer dielectric 179, and the plurality of first bonding metal pads 178 may be respectively formed in the plurality of local contact regions.

Referring to FIG. 11I, the resulting product of FIG. 11H may be aligned with the peripheral circuit structure PCS such that a surface of the resulting product of FIG. 11H, at which the plurality of first bonding metal pads 178 and the third interlayer dielectric 169 adjacent to the plurality of bit lines BL are exposed, faces the peripheral circuit structure PCS, and the plurality of first bonding metal pads 178 may be respectively bonded to the plurality of second bonding metal pads 278 of the peripheral circuit structure PCS. In some embodiments, the plurality of first bonding metal pads 178 may be respectively and directly bonded to the plurality of second bonding metal pads 278 without a separate adhesive layer by pressurizing the peripheral circuit structure PCS in a direction of an arrow AR1. For example, in at least one embodiment, the plurality of first bonding metal pads 178 may be respectively and directly bonded to the plurality of second bonding metal pads 278 may be bonded through hybrid bonding. In some embodiments, before the plurality of first bonding metal pads 178 are respectively bonded to the plurality of second bonding metal pads 278, a process of treating the exposed surface of each of the plurality of first bonding metal pads 178 and the plurality of second bonding metal pads 278 with hydrogen plasma may further performed to enhance the adhesion of each thereof.

In addition, after a plurality of cell array structures CAS having the same or a substantially similar structures are formed through the processes of FIGS. 11A to 11G, one of the plurality of cell array structures CAS formed as such may be used as the lower cell array structure LCAS, and another one of the plurality of cell array structures CAS may be used as the upper cell array structure UCAS. The upper cell array structure UCAS may be aligned with the lower cell array structure LCAS such that a surface of the upper cell array structure UCAS, at which the plurality of first bonding metal pads 178 and the fourth interlayer dielectric 179 adjacent to the upper substrate 110 are exposed, faces a surface of the lower cell array structure LCAS, at which the plurality of first bonding metal pads 178 and the third interlayer dielectric 169 adjacent to the plurality of bit lines BL are exposed, and then, the plurality of first bonding metal pads 178 of the upper cell array structure UCAS may be respectively bonded to the plurality of first bonding metal pads 178 of the lower cell array structure LCAS by pressurizing the upper cell array structure UCAS in a direction of an arrow AR2, thereby manufacturing the semiconductor device 100 shown in FIG. 6.

In some embodiments, after the process described with reference to FIG. 11I is performed, a process of bonding yet another one of the plurality of cell array structures CAS, which are formed through the processes of FIGS. 11A to 11G, onto the upper cell array structure UCAS may be further performed. By repeatedly performing such processes, a semiconductor device including a plurality of cell array structures (that is, CAS1, CAS2, . . . , and CASn) stacked in the vertical direction (the Z direction) on the peripheral circuit structure PCS as described with reference to FIG. 2B may be formed.

Heretofore, while the example of the method of manufacturing the semiconductor device 100 shown in FIGS. 3 to 6 have been described with reference to FIGS. 11A to 11I, it will be understood by those of ordinary skill in the art that, by making various modifications and changes to the example described with reference to FIGS. 11A to 11I, the semiconductor devices 100A, 300, 400, and 500 described with reference to FIGS. 7A to 10 and semiconductor devices having various structures modified and changed therefrom without departing from the spirit and scope of the inventive concepts may be manufactured.

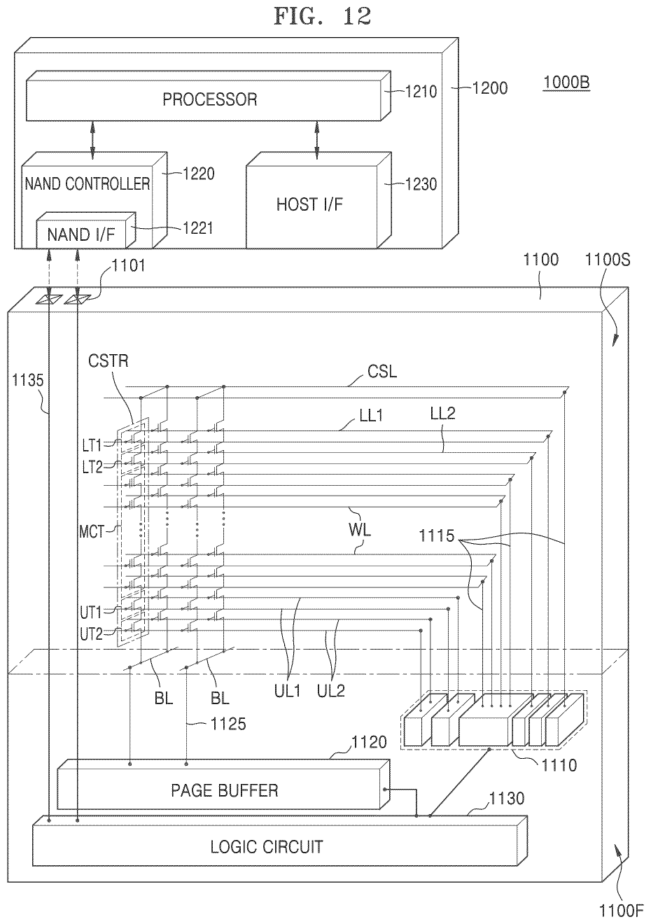

FIG. 12 is a diagram schematically illustrating an electronic system including a semiconductor device according to at least one embodiment.

Referring to FIG. 12, an electronic system 1000B according to at least one embodiment may include a semiconductor device 1100 and a controller 1200 that is electrically connected with the semiconductor device 1100. The electronic system 1000B may include a storage device including one or more semiconductor devices 1100 or an electronic device including a storage device. For example, the electronic system 1000B may include a solid-state drive (SSD) device, a universal serial bus (USB), a computing system, a medical device, or a communication device, which includes at least one semiconductor device 1100.

The semiconductor device 1100 may include a nonvolatile memory device. For example, the semiconductor device 1100 may include a NAND flash memory device including at least one of the structures of the semiconductor devices 10, 10A, 10B, 100, 100A, 200, 300, 400, and 500 described with reference to FIGS. 1 to 10. The semiconductor device 1100 may include a first structure 1100F and a second structure 1100S on the first structure 1100F. In some embodiments, the first structure 1100F may be arranged beside the second structure 1100S. The first structure 1100F may include a peripheral circuit structure, which includes a decoder circuit 1110, a page buffer 1120, and a logic circuit 1130. The second structure 1100S may include a memory cell structure, which includes a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The respective numbers of lower transistors LT1 and LT2 and upper transistors UT1 and UT2 may be variously modified depending on embodiments.

In some embodiments, the upper transistors UT1 and UT2 may include a string select transistor and the lower transistors LT1 and LT2 may include a ground select transistor. A plurality of gate lower lines (that is, LL1 and LL2) may be gate electrodes of the lower transistors LT1 and LT2, respectively. A word line WL may be a gate electrode of a memory cell transistor MCT, and a plurality of gate upper lines (that is, UL1 and UL2) may be gate electrodes of the upper transistors UT1 and UT2, respectively.

The common source line CSL, the plurality of gate lower lines (that is, LL1 and LL2), the plurality of word lines WL, and the plurality of gate upper lines (that is, UL1 and UL2) may be electrically connected with the decoder circuit 1110 via a plurality of first connection wiring lines 1115 extending from inside the first structure 1100F to the second structure 1100S. A plurality of bit lines BL may be electrically connected with the page buffer 1120 via a plurality of second connection wiring lines 1125 extending from inside the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 via an input/output pad 1101 electrically connected with the logic circuit 1130. The input/output pad 1101 may be electrically connected with the logic circuit 1130 via an input/output connection wiring line 1135 extending from inside the first structure 1100F to the second structure 1100S.

The controller 1200 may include a processor 1210, a NAND controller 1220, and a host interface 1230. Depending on embodiments, the electronic system 1000B may include a plurality of semiconductor devices 1100, and in this case, the controller 1200 may control the plurality of semiconductor devices 1100.

The processor 1210 may control all operations of the electronic system 1000B including the controller 1200. The processor 1210 may be operated by certain firmware and may access the semiconductor device 1100 by controlling the NAND controller 1220. The NAND controller 1220 may include a NAND interface 1221 that processes communication with the semiconductor device 1100. A control command for controlling the semiconductor device 1100, data intended to be written to the plurality of memory cell transistors MCT of the semiconductor device 1100, data intended to be read from the plurality of memory cell transistors MCT, and the like may be transmitted via the NAND interface 1221. The host interface 1230 may provide a function of communication between the electronic system 1000B and an external host. When receiving a control command from the external host via the host interface 1230, the processor 1210 may control the semiconductor device 1100 in response to the control command.

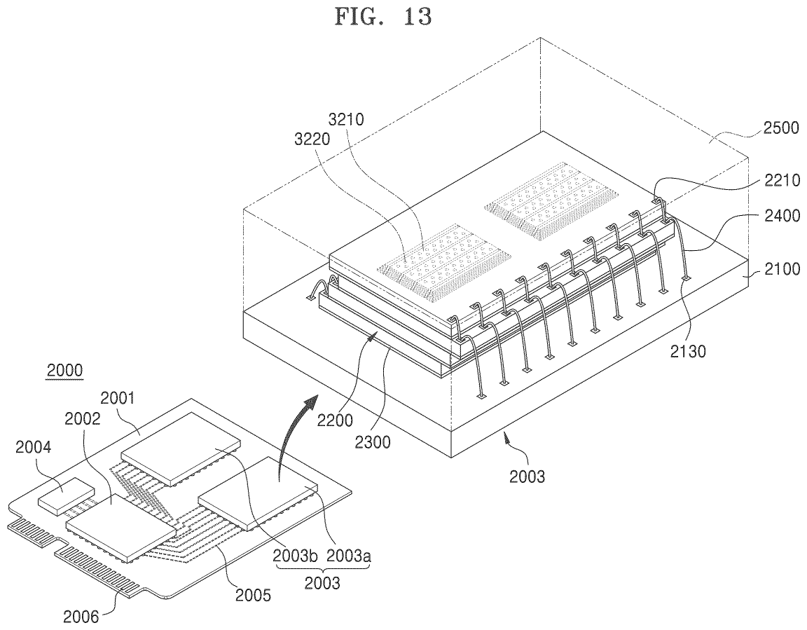

FIG. 13 is a perspective view schematically illustrating an electronic system including a semiconductor device according to at least one embodiment.

Referring to FIG. 13, an electronic system 2000 according to at least one embodiment may include a main substrate 2001, and a controller 2002, one or more semiconductor packages 2003, and DRAM 2004, which are mounted on the main substrate 2001. The semiconductor packages 2003 and the DRAM 2004 may be connected with the controller 2002 by a plurality of wiring patterns 2005 formed on the main substrate 2001.

The main substrate 2001 may include a connector 2006 including a plurality of pins to be coupled with an external host. The number of pins and the arrangement of the plurality of pins, in the connector 2006, may vary depending on a communication interface between the electronic system 2000 and the external host. In some embodiments, the electronic system 2000 may communicate with the external host according to one of interfaces, such as Universal Serial Bus (USB), Peripheral Component Interconnect Express (PCI-Express), Serial Advanced Technology Attachment (SATA), and M-Phy for Universal Flash Storage (UFS). In some embodiments, the electronic system 2000 may be operated by power supplied from the external host via the connector 2006. The electronic system 2000 may further include a power management integrated circuit (PMIC) distributing the power, which is supplied from the external host, to the controller 2002 and the semiconductor packages 2003.

The controller 2002 may write data to or read data from the semiconductor packages 2003 and may improve an operation speed of the electronic system 2000.

The DRAM 2004 may be a buffer memory for alleviating a speed difference between the external host and the semiconductor packages 2003, which are data storage spaces. The DRAM 2004 in the electronic system 2000 may operate as a kind of cache memory and may provide a space for temporarily storing data in a control operation on the semiconductor packages 2003. When the DRAM 2004 is included in the electronic system 2000, the controller 2002 may further include a DRAM controller for controlling the DRAM 2004 in addition to a NAND controller for controlling the semiconductor packages 2003.

The semiconductor package 2003 may include first and second semiconductor packages 2003a and 2003b, which are apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 with the package substrate 2100, and a molding layer 2500 arranged on the package substrate 2100 to cover the plurality of semiconductor chips 2200 and the connection structure 2400.

The package substrate 2100 may include a printed circuit board including a plurality of package upper pads 2130. Each of the plurality of semiconductor chips 2200 may include an input/output pad 2210. The input/output pad 2210 may correspond to the input/output pad 1101 of FIG. 8A or 8B. Each of the plurality of semiconductor chips 2200 may include a plurality of gate stacks 3210 and a plurality of channel structures 3220. Each of the plurality of semiconductor chips 2200 may include at least one of the structures of the semiconductor devices 10, 10A, 10B, 100, 100A, 200, 300, 400, and 500 described with reference to FIGS. 1 to 10.

In some embodiments, the connection structure 2400 may include a bonding wire electrically connecting the input/output pad 2210 with a package upper pad 2130. Therefore, in the first and second semiconductor packages 2003a and 2003b, the plurality of semiconductor chips 2200 may be electrically connected to each other in a bonding wire manner and may be electrically connected with the package upper pads 2130 of the package substrate 2100. In some embodiments, in the first and second semiconductor packages 2003a and 2003b, the plurality of semiconductor chips 2200 may be electrically connected to each other by a connection structure including a through-silicon via (TSV) rather than by the connection structure 2400 of a bonding wire type.

In some embodiments, the controller 2002 and the plurality of semiconductor chips 2200 may be included in one package. In some embodiments, the controller 2002 and the plurality of semiconductor chips 2200 may be mounted on a separate interposer substrate, which is different from the main substrate 2001, and may be connected to each other by wiring lines formed on the interposer substrate.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a peripheral circuit structure comprising a circuit substrate and a plurality of circuits on the circuit substrate;
a lower cell array structure overlapping the peripheral circuit structure in a vertical direction, the lower cell array structure comprising a plurality of lower vertical channel structures;
an upper cell array structure overlapping the peripheral circuit structure in the vertical direction such that the lower cell array structure is between the peripheral circuit structure and the upper cell array structure, the upper cell array structure comprising a plurality of upper vertical channel structures; and
a plurality of bit lines including a plurality of lower bit lines connected the plurality of lower vertical channel structures and a plurality of upper bit lines connected to the plurality of upper vertical channel structures,
wherein the plurality of lower bit lines comprise
a first lower bit line connected to a first group of the plurality of lower vertical channel structures, and
a second lower bit line connected to a second group of the plurality of lower vertical channel structures, the second group selected from a remainder of the plurality of lower vertical channel structures which are spaced apart from the first group of lower vertical channel structures,
wherein the first lower bit line and the second lower bit line are spaced apart from each other in a first horizontal direction and extend along a first straight line in the first horizontal direction at a first vertical level over the circuit substrate, and
the plurality of upper bit lines comprise
an upper bit line connected to a first group of the plurality of upper vertical channel structures, and
an upper connection bit line connected to the upper bit line,
wherein the upper bit line connected to the first group of upper vertical channel structures is at a second vertical level and the upper connection bit line is at the first vertical level, and
wherein the second vertical level is farther from the circuit substrate than the first vertical level.

2. The semiconductor device of claim 1, wherein the first lower bit line, the upper connection bit line, and the second lower bit line are sequentially spaced apart from each other the first straight line at the first vertical level.

3. The semiconductor device of claim 1, further comprising:
a plurality of through-contact plugs passing through the lower cell array structure in the vertical direction, the plurality of through-contact plugs including a through-contact plug configured to connect the upper bit line to the upper connection bit line.

4. The semiconductor device of claim 1, further comprising:
a plurality of wiring layers between the peripheral circuit structure and the lower cell array structure, the plurality of wiring layers including a first wiring layer connecting the first and second lower bit lines.

5. The semiconductor device of claim 1, further comprising:
a plurality of through-contact plugs passing through the lower cell array structure in the vertical direction; and
a plurality of wiring layers between the peripheral circuit structure and the lower cell array structure,
wherein the first lower bit line and the second lower bit line are connected to a first circuit, of the plurality of circuits of the peripheral circuit structure, through a first wiring layer of the plurality of wiring layers,
wherein the upper bit line is connected to the first circuit through at least one of the plurality of through-contact plugs, the upper connection bit line, and a second wiring layer, of the plurality of wiring layers, and
wherein the second wiring layer is spaced apart from the first wiring layer.

6. The semiconductor device of claim 1, further comprising:
a plurality of wiring layers between the peripheral circuit structure and the lower cell array structure;
a plurality of lower bonding structures between the plurality of wiring layers and the peripheral circuit structure; and
a plurality of upper bonding structures between the lower cell array structure and the upper cell array structure,
wherein the first lower bit line and the second lower bit line are connected to a first circuit, of the plurality of circuits of the peripheral circuit structure, through a first wiring layer, of the plurality of wiring layers, and at least one of the plurality of lower bonding structures,
wherein the upper bit line is connected to the first circuit through at least one of the plurality of upper bonding structures, the upper connection bit line, a second wiring layer, and second lower bonding structure of the plurality of lower bonding structures,
wherein the second wiring layer is spaced apart from the first wiring layer.

7. The semiconductor device of claim 1, further comprising:
a pair of dam structures passing through the lower cell array structure and extending lengthwise in a second horizontal direction that is orthogonal to the first horizontal direction;
an insulating structure passing through the lower cell array structure in an area defined by the pair of dam structures; and
a plurality of through-contact plugs passing through the insulating structure in the vertical direction,
wherein the plurality of lower bit lines and the plurality of upper bit lines each extend lengthwise in the first horizontal direction,
wherein the upper connection bit line is connected to the upper bit line through at least one of the plurality of through-contact plugs, and
wherein the plurality of lower bit lines are not connected to any of the plurality of through-contact plugs.

8. The semiconductor device of claim 7, wherein, in a plan view, a size of each of the plurality of through-contact plugs is equal to a size of each of the plurality of lower vertical channel structures, and
in comparative unit planar areas, a density of the plurality of through-contact plugs is equal to a density of the plurality of lower vertical channel structures.

9. The semiconductor device of claim 7, wherein, in a plan view, a size of each of the plurality of through-contact plugs is greater than a size of each of the plurality of lower vertical channel structures, and
in comparative unit planar areas, a density of the plurality of through-contact plugs is less than a density of the plurality of lower vertical channel structures.

10. The semiconductor device of claim 7, further comprising:
a plurality of dummy insulating plugs passing through the insulating structure in the vertical direction,
wherein the plurality of dummy insulating plugs form a hexagonal array with the plurality of through-contact plugs, and
wherein the plurality of lower bit lines further comprise a third lower bit line passing over at least one of the plurality of dummy insulating plugs to overlap the at least one dummy insulating plug in the vertical direction.

11. The semiconductor device of claim 7, further comprising:
a plurality of dummy insulating plugs passing through the insulating structure in the vertical direction,
wherein the plurality of dummy insulating plugs comprise
a plurality of first dummy insulating plugs passing through the insulating structure in the vertical direction in a first local area between the plurality of through-contact plugs and the first group of lower vertical channel structures, and
a plurality of second dummy insulating plugs passing through the insulating structure in the vertical direction in a second local area between the plurality of through-contact plugs and the second group of lower vertical channel structures, and
wherein the plurality of lower bit lines further comprise a third lower bit line, which passes over at least one of the plurality of first dummy insulating plugs or at least one of the plurality of second dummy insulating plugs.

12. A semiconductor device comprising:
a peripheral circuit structure comprising a circuit substrate and a plurality of circuits on the circuit substrate;
a lower cell array structure overlapping the peripheral circuit structure in a vertical direction, the lower cell array structure comprising a plurality of lower vertical channel structures;
an insulating structure passing through a portion of the lower cell array structure in the vertical direction;
an upper cell array structure overlapping the peripheral circuit structure in the vertical direction such that the lower cell array structure is between the peripheral circuit structure and the upper cell array structure, the upper cell array structure comprising a plurality of upper vertical channel structures;
a plurality of bit lines including a plurality of lower bit lines connected the plurality of lower vertical channel structures and a plurality of upper bit lines connected to the plurality of upper vertical channel structures; and
a plurality of through-contact plugs passing through the insulating structure in the vertical direction,
wherein the plurality of lower bit lines comprise
a first lower bit line connected to a first group of the plurality of lower vertical channel structures, and
a second lower bit line connected to a second group of the plurality of lower vertical channel structures, the second group selected from a remainder the plurality of lower vertical channel structures which are apart from the first group of lower vertical channel structures,
wherein the first lower bit line and the second lower bit line are spaced apart from each other in a first horizontal direction, with the insulating structure and the plurality of through-contact plugs therebetween, and
the plurality of upper bit lines comprise
an upper bit line connected to a first group of the plurality upper vertical channel structures, and
an upper connection bit line connected the upper bit line through at least one of the plurality of through-contact plugs,
wherein first lower bit line, the upper connection bit line, and the second lower bit line are sequentially arranged on a first straight line at a first vertical level.

13. The semiconductor device of claim 12, further comprising:
a plurality of wiring layers between the peripheral circuit structure and the lower cell array structure,
wherein the first lower bit line and the second lower bit line are connected to a first circuit of the plurality of circuits of the peripheral circuit structure through a first wiring layer of the plurality of wiring layers, and
wherein the upper bit line are connected to the first circuit through the at least one of the plurality of through-contact plug, the upper connection bit line, and a second wiring layer of the plurality of wiring layers, and
wherein the second wiring layer is spaced apart from the first wiring layer.

14. The semiconductor device of claim 12, further comprising:
a plurality of wiring layers between the peripheral circuit structure and the lower cell array structure;
a plurality of lower bonding structures between the plurality of wiring layers and the peripheral circuit structure; and
a plurality of upper bonding structures between the lower cell array structure and the upper cell array structure,
wherein each of the first lower bit line and the second lower bit line are connected to a first circuit of the plurality of circuits of the peripheral circuit structure through a first wiring layer of the plurality of wiring layers and at least one first lower bonding structure of the plurality of lower bonding structures, and
the upper bit line is connected to the first circuit through at least one of the plurality of upper bonding structures, the at least one of the plurality of through-contact plugs, the upper connection bit line, a second wiring layer of the plurality of wiring structures, and at least one second lower bonding structure of the plurality of lower bonding structures.

15. The semiconductor device of claim 12, further comprising:
a plurality of memory cell blocks overlapping the peripheral circuit structure in the vertical direction and extending lengthwise in a second horizontal direction, the second horizontal direction orthogonally intersecting with the first horizontal direction;
a plurality of word line cut regions respectively arranged on both sides of each of the plurality of memory cell blocks such that each of the plurality of word line cut regions are spaced apart from each other in the first horizontal direction and such that a pair of the plurality of word line cut regions defines a width of each of the plurality of memory cell blocks in the first horizontal direction; and
a pair of dam structures extending lengthwise in the second horizontal direction and arranged between two adjacent memory blocks selected from the plurality of memory cell blocks,
wherein the insulating structure extends lengthwise in the second horizontal direction between the pair of dam structures.

16. The semiconductor device of claim 12, wherein, in a plan view, a size of each of the plurality of through-contact plugs is equal to a size of each of the plurality of lower vertical channel structures, and
in comparative unit planar areas, a density of the plurality of through-contact plugs is equal to a density of the plurality of lower vertical channel structures.

17. The semiconductor device of claim 12, wherein, in a plan view, a size of each of the plurality of through-contact plugs is greater than a size of each of the plurality of lower vertical channel structures, and
in comparative unit planar areas, a density of the plurality of through-contact plugs is less than a density of the plurality of lower vertical channel structures.

18. The semiconductor device of claim 12, further comprising:
a plurality of dummy insulating plugs passing through the insulating structure in the vertical direction,
wherein the plurality of dummy insulating plugs form a hexagonal array with the plurality of through-contact plugs, and
wherein the plurality of lower bit lines further comprise a third lower bit line passing over at least one of the plurality of dummy insulating plugs.

19. The semiconductor device of claim 12, further comprising:
a plurality of dummy insulating plugs passing through the insulating structure in the vertical direction,
wherein the plurality of dummy insulating plugs comprise
a plurality of first dummy insulating plugs passing through the insulating structure in the vertical direction in a first local area between the plurality of through-contact plugs and the first group of lower vertical channel structures, and
a plurality of second dummy insulating plugs passing through the insulating structure in the vertical direction in a second local area between the plurality of through-contact plugs and the second group of lower vertical channel structures, and
wherein the plurality of lower bit lines further comprise a third lower bit line, which passes over at least one of the plurality of first dummy insulating plugs or at least one of the plurality of second dummy insulating plugs.

20. An electronic system comprising:
a main substrate;
a semiconductor device on the main substrate; and
a controller on the main substrate and electrically connected to the semiconductor device,
wherein the semiconductor device comprises
a peripheral circuit structure comprising a circuit substrate and a plurality of circuits on the circuit substrate,
a lower cell array structure overlapping the peripheral circuit structure in a vertical direction, the lower cell array structure comprising a plurality of lower vertical channel structures,
an upper cell array structure overlapping the peripheral circuit structure in the vertical direction such that the lower cell array structure is between the upper cell array structure and the peripheral circuit structure, the upper cell array structure comprising a plurality of upper vertical channel structures,
a plurality of bit lines, the plurality of bit lines including a plurality of lower bit lines connected the plurality of lower vertical channel structure, and a plurality of upper bit lines connected to the plurality of upper vertical channel structures, and
an input/output pad electrically connected to the peripheral circuit structure, wherein the plurality of lower bit lines comprise
a first lower bit line connected to a first group of the plurality of lower vertical channel structures, and
a second lower bit line connected to a second group of the plurality of lower vertical channel structures, the second group selected from a remainder of the plurality of lower vertical channel structures which are apart from the first group of lower vertical channel structures,
wherein the first lower bit line and the second lower bit line are spaced apart from each other in a first horizontal direction and extend along a first straight line in the first horizontal direction at a first vertical level over the circuit substrate, and
the plurality of upper bit lines comprise
an upper bit line connected to a first group of the plurality of upper vertical channel structures, and
an upper connection bit line connected to the upper bit line,
wherein the upper bit line connected to the first group of upper vertical channel structures is at a second vertical level and the upper connection bit line is at the first vertical level, and
wherein the second vertical level is farther from the circuit substrate than the first vertical level.
